(19) United States
(12) Patent Application Publication
(10) Pub. No.: US 2024/0049508 A1
(43) Pub. Date: Feb. 8, 2024

(54) DISPLAY DEVICE AND METHOD OF MANUFACTURING THE SAME

(71) Applicant: SAMSUNG DISPLAY CO., LTD., Yongin-si (KR)

(72) Inventors: Jeongseok LEE, Yongin-si (KR); Seungyong SONG, Yongin-si (KR); Wooyong SUNG, Yongin-si (KR)

(21) Appl. No.: 18/144,613

(22) Filed: May 8, 2023

(30) Foreign Application Priority Data
Aug. 5, 2022 (KR) 10-2022-0098129

(51) Int. Cl. H10K 59/121; H10K 59/131; H10K 59/12; H10K 71/20; H10K 59/123; H10K 59/80; H10K 59/35

(52) U.S. Cl. CPC H10K 59/1213; H10K 59/1315; H10K 59/1201; H10K 71/233; H10K 59/123; H10K 59/873; H10K 59/35

(57) ABSTRACT

A display device includes a first electrode connected with the thin-film transistor; a first insulating layer covering an edge of the first electrode and extending to the non-pixel area; a first protective layer arranged between the first electrode and the first insulating layer; a metal stacked structure disposed on the first insulating layer in the non-pixel area, where the metal stacked structure includes a plurality of sub-metal layers; a first portion of the intermediate layer disposed on the first electrode; a first portion of a second electrode disposed on the first portion of the intermediate layer; and a second portion of the intermediate layer and a second portion of the second electrode disposed on the metal stacked structure, where first portions of the intermediate layer and the second electrode is disconnected from second portions of the first intermediate layer and the first electrode by the metal stacked structure.

This application claims priority to Korean Patent Application No. 10-2022-0098129, filed on Aug. 5, 2022, and all the benefits accruing therefrom under 35 U.S.C. § 119, the content of which in its entirety is herein incorporated by reference.

### BACKGROUND

### 1. Field

One or more embodiments relate to a structure of a display device.

### 2. Description of the Related Art

Display apparatuses may visually display data. Such display devices may include a substrate including a display area and a peripheral area. The display area may be provided with a scan line and a data line that are insulated from each other, and may include a plurality of pixels. In addition, the display area may include a thin-film transistor corresponding to each of the pixels and a sub-pixel electrode electrically connected to the thin-film transistor. In addition, the display area may include opposite electrodes commonly included in the pixels. A peripheral area may include various wiring, scan drivers, data drivers, controllers, and pad units that transmit electrical signals to the display area.

Recently, display devices are widely used in various fields. Accordingly, various designs have been attempted to improve the quality of the display device.

### SUMMARY

One or more embodiments include a display device that may improve resolution and implement an image of high quality.

According to one or more embodiments, a display device includes a first sub-pixel, a second sub-pixel, and a third sub-pixel, which emit light of different colors from each other, a substrate, on which a pixel area, in which the first sub-pixel, the second sub-pixel and the third sub-pixel are arranged, and a non-pixel area, in which a plurality of sub-pixels are not arranged, are defined, a thin-film transistor disposed on the substrate, a planarization layer covering the thin-film transistor, a first electrode disposed on the planarization layer and connected to the thin-film transistor, a first insulating layer covering an edge of the first electrode and extending to the non-pixel area, a first protective layer disposed between the first electrode and the first insulating layer, a metal stacked structure disposed on the first insulating layer in the non-pixel area, where the metal stacked structure includes a plurality of sub-metal layers, a first portion of an intermediate layer disposed on the first electrode, a first portion of a second electrode disposed on the first portion of the intermediate layer, and a second portion of the intermediate layer and a second portion of the second electrode disposed on the metal stacked structure, where the first portion of the intermediate layer and the first portion of the second electrode are disconnected from the second portion of the intermediate layer and the second portion of the second electrode by the metal stacked structure.

According to one or more embodiments, the first portion of the second electrode may be electrically connected to the metal stacked structure, and the metal stacked structure may be connected to a power voltage line.

According to one or more embodiments, the metal stacked structure may include a first sub-metal layer and a second sub-metal layer having different etching ratios from each other, a first hole corresponding to an emission area of the plurality of sub-pixels may be defined in the first sub-metal layer, and a second hole may be defined in the second sub-metal layer under the first sub-metal layer, where the second hole may have a diameter greater than a diameter of the first hole and overlap the first hole.

According to one or more embodiments, an edge of the first sub-metal layer defining the first hole may protrude toward a center of the first hole from a point where a side surface of the second sub-metal layer defining the second hole meets a bottom surface of the first sub-metal layer, and the first portion of the intermediate layer and the first portion of the second electrode may be disposed in the second hole.

According to one or more embodiments, the first portion of the second electrode may contact the side surface of the second sub-metal layer defining the second hole.

According to one or more embodiments, the metal stacked structure may further include a third sub-metal layer disposed under the second sub-metal layer, and the third sub-metal layer may include the same material as the first sub-metal layer.

According to one or more embodiments, the metal stacked structure may have a planar shape of a mesh pattern.

According to one or more embodiments, the first protective layer may include a transparent conductive oxide (TCO).

According to one or more embodiments, the display device may further include a thin-film encapsulation layer at least partially filling the first hole and the second hole.

According to one or more embodiments, the intermediate layer may include an organic emission layer which emits light, and

the organic emission layer of each of the first sub-pixel, the second sub-pixel, and the third sub-pixel may emit light of different colors from each other.

According to one or more embodiments, the second portion of the intermediate layer and the second portion of the second electrode may extend to the non-pixel area.

According to one or more embodiments, a second portion of an intermediate layer of the first sub-pixel, a second portion of an intermediate layer of the second sub-pixel, and a second portion of an intermediate layer of the third sub-pixel may be sequentially stacked on the metal stacked structure.

According to one or more embodiments, the display device may further include a thin-film encapsulation layer filling areas between the second portion of the intermediate layer of the first sub-pixel, the second portion of the intermediate layer of the second sub-pixel, and the second portion of the intermediate layer of the third sub-pixel.

According to one or more embodiments, a method of manufacturing a display device including a pixel area in which a first sub-pixel, a second sub-pixel, and a third sub-pixel, which emit light of different colors from each other are arranged, and a non-pixel area in which a plurality of sub-pixels are not arranged, includes providing a thin-film transistor on a substrate, providing a planarization layer to cover the thin-film transistor, providing a sub-pixel electrode on the planarization layer, where the sub-pixel electrode is connected to the thin-film transistor, providing a first insulating layer covering an edge of the sub-pixel electrode and extending to the non-pixel area, providing a metal stacked structure on the first insulating layer, where the metal stacked structure includes a first sub-metal layer and a second sub-metal layer, forming a first hole, corresponding to an emission area of the first sub-pixel, in the first sub-metal layer, forming a second hole in the second sub-metal layer disposed under the first sub-metal layer, where the second hole has a diameter greater than a diameter of the first hole and overlaps the first hole, providing a first portion of a first intermediate layer on the sub-pixel electrode of the first sub-pixel, providing a first portion of a first opposite electrode on the first portion of the first intermediate layer, and providing a second portion of the first intermediate layer and a second portion of the first opposite electrode on the metal stacked structure, where the first portion of the first intermediate layer and the first portion of the first electrode are disconnected from the second portion of the intermediate layer and the first portion of the second electrode by the metal stacked structure.

According to one or more embodiments, the forming the first hole may include forming a photoresistor on the metal stacked structure and performing a photolithography process, and performing dry etching on the first sub-metal layer and the second sub-metal layer.

According to one or more embodiments, the forming the second hole may include etching the second sub-metal layer in a way that an edge of the first sub-metal layer defining the first hole protrudes more toward a center of the first hole from a point where a side surface of the second sub-metal layer defining the second hole meets a bottom surface of the first sub-metal layer.

According to one or more embodiments, the method may further include forming a hole overlapping the first hole in the first insulating layer by performing dry etching.

According to one or more embodiments, the method may further include providing a first protective layer between the first insulating layer and the sub-pixel electrode, and forming a hole overlapping the first hole in the first protective layer by wet etching.

According to one or more embodiments, the method may further include providing a first thin-film encapsulation layer to at least partially fill the first hole and the second hole.

According to one or more embodiments, the method may further include performing dry etching on portions of the second portion of the first intermediate layer, the second portion of the first opposite electrode, and the first thin-film encapsulation layer, which are arranged in remaining areas excluding the pixel area of the first sub-pixel.

According to one or more embodiments, the method may further include forming a third hole corresponding to an emission area of the second sub-pixel in the first sub-metal layer, forming a fourth hole in the second sub-metal layer, where the fourth hole may have a diameter greater than a diameter of the third hole and overlap the third hole, providing a first portion of a second intermediate layer on the sub-pixel electrode of the second sub-pixel, providing a first portion of a second opposite electrode on the first portion of the second intermediate layer, providing a second portion of the second intermediate layer and a second portion of the second opposite electrode on the metal stacked structure, providing a second thin-film encapsulation layer to fill at least a portion of the third hole and the fourth hole, and performing dry etching on portions of the second portion of the second intermediate layer, the second portion of the second opposite electrode, and the second thin-film encapsulation layer, which are arranged in remaining areas excluding the pixel area of the second sub-pixel.

According to one or more embodiments, the method may further include forming a fifth hole corresponding to an emission area of the third sub-pixel in the first sub-metal layer, forming a sixth hole in the second sub-metal layer, where the sixth hole may have a diameter greater than a diameter of the fifth hole and overlap the fifth hole, providing a first portion of a third intermediate layer on the sub-pixel electrode of the third sub-pixel, providing a first portion of a third opposite electrode on the first portion of the third intermediate layer, providing a second portion of the third intermediate layer and a second portion of the third opposite electrode on the metal stacked structure, providing a third thin-film encapsulation layer to fill at least a portion of the fifth hole and the sixth hole, and performing dry etching on portions of the second portion of the third intermediate layer, the second portion of the third opposite electrode, and the third thin-film encapsulation layer arranged in remaining areas excluding the pixel area of the third sub-pixel.

According to one or more embodiments, the method may further include forming a third hole corresponding to the emission area of the second sub-pixel in the first sub-metal layer, the second portion of the first intermediate layer, and the first thin-film encapsulation layer, forming a fourth hole in the second sub-metal layer, where the fourth hole may have a diameter greater than a diameter of the third hole and overlapping the third hole, providing a first portion of a second intermediate layer on the sub-pixel electrode of the second sub-pixel, providing a first portion of a second opposite electrode on the first portion of the second intermediate layer, providing a second portion of the second intermediate layer and a second portion of the second opposite electrode on the metal stacked structure, and providing a second thin-film encapsulation layer to at least partially fill the third hole and the fourth hole.

According to one or more embodiments, the method may further include forming a fifth hole corresponding to the emission area of the third sub-pixel in the first sub-metal layer, the second portion of the first intermediate layer, the second portion of the first opposite electrode, the first thin-film encapsulation layer, the second portion of the second intermediate layer, the second portion of the second opposite electrode, and the second thin-film encapsulation layer, forming a sixth hole in the second sub-metal layer, where the sixth hole may have a diameter greater than a diameter of the fifth hole and overlap the fifth hole, providing a first portion of a third intermediate layer on the sub-pixel electrode of the third sub-pixel, providing a first portion of a third opposite electrode on the first portion of the third intermediate layer, providing a second portion of the third intermediate layer and a second portion of the third opposite electrode on the metal stacked structure, and providing a third thin-film encapsulation layer to at least partially fill the fifth hole and the sixth hole.

According to one or more embodiments, the method may further include performing dry etching on materials on the emission area of the first sub-pixel excluding the first thin-film encapsulation layer, and performing dry etching on materials on the emission area of the second sub-pixel excluding the second thin-film encapsulation layer.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display device according to an embodiment;

FIGS. 2A and 2B are equivalent circuit diagrams of a light-emitting diode included in the display device and a pixel circuit electrically connected to the light-emitting diode, according to an embodiment;

FIG. 3A is a schematic cross-sectional view of the display device of FIG. 1 taken along line I-I′;

FIG. 3B is an enlarged view of the encircled portion B of FIG. 3A;

FIGS. 4A to 4I are cross-sectional views sequentially illustrating a process of manufacturing a display device according to an embodiment;

FIGS. 5A to 5F are cross-sectional views sequentially illustrating a process of manufacturing a display device according to an embodiment;

FIG. 6 is a cross-sectional view schematically illustrating a portion of a display device according to an alternative embodiment; and

FIGS. 7A to 7F are cross-sectional views sequentially illustrating a process of manufacturing a display device according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

When a certain embodiment may be implemented differently, a specific process order may be performed differently from the described order. For example, two consecutively described processes may be performed substantially at the same time or may be performed in an order opposite to the described order.

It will also be understood that when a layer, region, or component is referred to as being “connected” or “coupled” to another layer, region, or component, it can be directly connected or coupled to the other layer, region, or component or intervening layers, regions, or components may be present. For example, when layers, areas, elements or the like are referred to as being “electrically connected,” they may be directly electrically connected, or layers, areas or elements may be indirectly electrically connected, and an intervening layer, region, component, or the like may be present therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

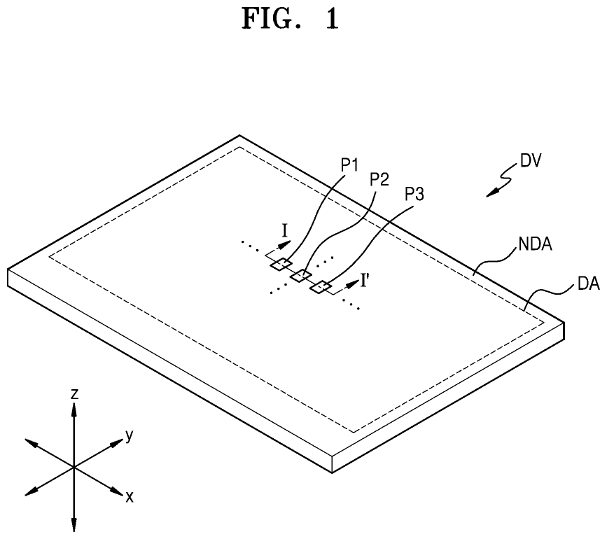

FIG. 1 is a schematic perspective view of a display device according to an embodiment.

Referring to FIG. 1, an embodiment of the display device DV may include a display area DA and a non-display area NDA outside of the display area DA. The display device DV may provide an image through an array of a plurality of pixels arranged in a two-dimensional manner on an x-y plane (i.e., a plane defined by an x-axis and a y-axis in FIG. 1) in the display area DA. In FIG. 1, a z-axis direction may correspond to a thickness direction of the display device DV. The plurality of sub-pixels may include a first sub-pixel P1, a second sub-pixel P2, and a third sub-pixel P3 and, hereinafter, for convenience of description, embodiments in which the first sub-pixel P1 is a red sub-pixel, the second sub-pixel P2 is a green subpixel, and the third sub-pixel is a blue subpixel will be described in detail.

The red sub-pixel, the green sub-pixel, and the blue sub-pixel are regions that may emit light of red, green, and blue, respectively, and the display device DV may provide an image by using light emitted from the sub-pixels.

The non-display area NDA is an area in which no images are provided, and may entirely surround the display area DA. A driver or main voltage line configured to provide electrical signals or power to pixel circuits may be arranged in the non-displayed area NDA. A pad, which is an area to which an electronic element or a printed circuit board may be electrically connected, may be arranged in the non-display area NDA.

The display area DA may have a polygonal shape including a quadrilateral shape as illustrated in FIG. 1. In an embodiment, for example, the display area DA may have a rectangular shape in which the horizontal length (e.g., an x-axis direction) is greater than the vertical length (e.g., a y-axis direction) or the horizontal length is less than the vertical length, or a square shape. Alternatively, the display area DA may have various shapes, such as an oval shape or a circular shape.

The display device DV may be applied to various products such as televisions, notebook computers, monitors, billboards, and Internet of Things (IoT), as well as portable electronic apparatuses such as mobile phones, smart phones, tablet personal computers (PCs), mobile communication terminals, electronic notebooks, electronic books, portable multimedia players (PMPs), navigation, and Ultra Mobile PCs (UMPCs). Also, the display device DV according to an embodiment may be applied to wearable devices such as smart watches, watch phones, glasses-type displays, and head-mounted displays (HMDs). Also, the display device DV according to an embodiment may be applied to a center information display (CID) located on a vehicle's instrument panel or a vehicle's center fascia or dashboard, a room mirror display replacing a vehicle's side mirror, or a display screen located at the rear side of a vehicle's front seat as entertainment for a passenger in a vehicle's rear seat.

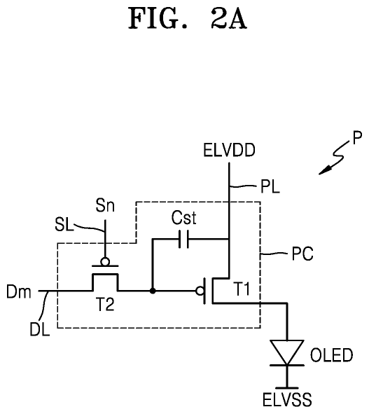

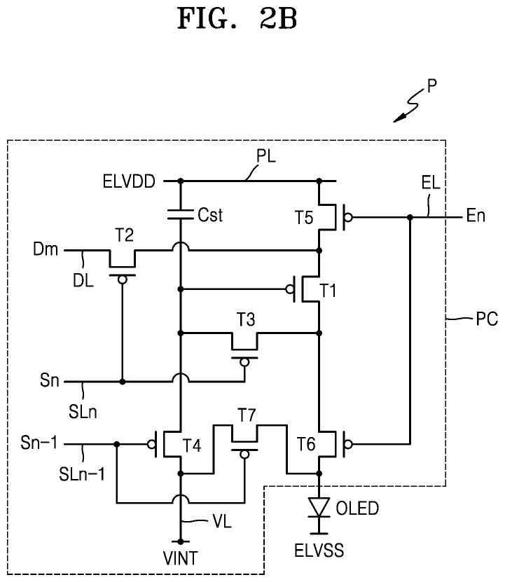

FIGS. 2A and 2B are equivalent circuit diagrams of a light-emitting diode included in the display device and a pixel circuit electrically connected to the light-emitting diode, according to an embodiment.

Referring to FIG. 2A, each sub-pixel may include a pixel circuit PC connected to a scan line SL and a data line DL and an organic light-emitting diode OLED connected to the pixel circuit PC.

The pixel circuit PC may include a driving thin-film transistor T1, a switching thin-film transistor T2, and a storage capacitor Cst. The switching thin-film transistor T2 may transmit a data signal Dm input through the data line DL to the driving thin-film transistor T1 in response to a scan signal Sn input through the scan line SL.

The storage capacitor Cst may be connected to the switching thin-film transistor T2 and a driving voltage line PL and may store a voltage corresponding to a difference between a voltage received from the switching thin-film transistor T2 and a first power voltage ELVDD (or driving voltage) supplied to the driving voltage line PL.

The driving thin-film transistor T1 may be connected to the driving voltage line L and the storage capacitor Cst and may be configured to control a driving current flowing through the organic light-emitting diode OLED from the driving voltage line PL in response to a voltage value stored in the storage capacitor Cst. The organic light-emitting diode OLED may emit light having a certain brightness corresponding to the driving current.

Although an embodiment in which the pixel circuit PC includes two thin-film transistors and one storage thin-film transistor is shown in FIG. 2A, the disclosure is not limited thereto.

Referring to FIG. 2B, in an alternative embodiment, the pixel circuit PC may include the driving thin-film transistor T1, the switching thin-film transistor T2, a compensation thin-film transistor T3, a first initialization thin-film transistor T4, a first emission control thin-film transistor T5, a second emission control thin-film transistor T6, and a second initialization thin-film transistor T7.

Although FIG. 2B shows signal lines SLn, SLn-1, EL, and DL, an initialization voltage line VL, and a driving voltage line PL provided for each sub-pixel P, the disclosure is not limited thereto. In an alternative embodiment, at least any one of the signal lines SLn, SLn-1, EL, and DL or/and the initialization voltage line VL may be shared by neighboring pixels.

A drain electrode of the driving thin-film transistor T1 may be electrically connected to the organic light-emitting diode OLED via the second emission control thin-film transistor T6. The driving thin-film transistor T1 is configured to receive the data signal Dm based on a switching operation of the switching thin-film transistor T2 and supply the driving current to the organic light-emitting diode OLED.

A gate electrode of the switching thin-film transistor T2 is connected to a first scan line SLn, and a source electrode of the switching thin-film transistor T2 is connected to the data line DL. A drain electrode of the switching thin-film transistor T2 may be connected to a source electrode of the driving thin-film transistor T1 and may also be connected to the driving voltage line PL via the first emission control thin-film transistor T5.

The switching thin-film transistor T2 is turned on in response to a first scan signal Sn received through the first scan line SLn to perform a switching operation for transmitting the data signal Dm transmitted through the data line DL to the source electrode of the driving thin-film transistor T1.

A gate electrode of the compensation thin-film transistor T3 may be connected to the first scan line SLn. A source electrode of the compensation thin-film transistor T3 may be connected to the drain electrode of the driving thin-film transistor T1 and may also be connected to a sub-pixel electrode of the organic light-emitting diode OLED via the second emission control thin-film transistor T6. A drain electrode of the compensation thin-film transistor T3 may be connected to one electrode of the storage capacitor Cst, a source electrode of the first initialization thin-film transistor T4, and a gate electrode of the driving thin-film transistor T1. The compensation thin-film transistor T3 is turned on according to the first scan signal Sn received through the first scan line SL to diode-connect the driving thin-film transistor T1 by connecting the gate electrode and the drain electrode of the driving thin-film transistor T1 to each other.

A gate electrode of the first initialization thin-film transistor T4 may be connected to a second scan line SLn-1 (e.g., a previous scan line). A drain electrode of the first initialization thin-film transistor T4 may be connected to the initialization voltage line VL. The source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be turned on in response to a second scan signal Sn-1 received through the second scan line SLn-1 to perform an initialization operation for initializing a voltage of the gate electrode of the driving thin-film transistor T1 by transmitting an initialization voltage VINT to the gate electrode of the driving thin-film transistor T1.

A gate electrode of the first emission control thin-film transistor T5 may be connected to an emission control line EL. A source electrode of the first emission control thin-film transistor T5 may be connected to the driving voltage line PL. A drain electrode of the first emission control thin-film transistor T5 is connected to the source electrode of the driving thin-film transistor T1 and the drain electrode of the switching thin-film transistor T2.

A gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. A drain electrode of the second emission control thin-film transistor T6 may be electrically connected to the sub-pixel electrode of the organic light-emitting diode OLED. As the first emission control thin-film transistor T5 and the second emission control thin-film transistor T6 are simultaneously turned on in response to an emission control signal En received through the emission control line EL, the first power voltage ELVDD is transmitted to the organic light-emitting diode OLED, and the driving current flows through the organic light-emitting diode OLED.

A gate electrode of the second initialization thin-film transistor T7 may be connected to the second scan line SLn-1. A source electrode of the second initialization thin-film transistor T7 may be connected to the sub-pixel electrode of the organic light-emitting diode OLED. A drain electrode of the second initialization thin-film transistor T7 may be connected to the initialization voltage line VL. The second initialization thin-film transistor T7 may be turned on in response to the second scan signal Sn-1 received through the second scan line SLn-1 to initialize the sub-pixel electrode of the organic light-emitting diode OLED.

Although FIG. 2B shows an embodiment where the first initialization thin-film transistor T4 and the second initialization thin-film transistor T7 are connected to the second scan line SLn-1, the disclosure is not limited thereto. In an alternative embodiment, the first initialization thin-film transistor T4 may be connected to the second scan line SLn-1, which is the previous scan line, to be driven based on the second scan signal Sn-1, and the second initialization thin-film transistor T7 may be connected to a separate signal line (e.g., a next scan line) so as to be driven based on the signal transmitted to the corresponding scan line.

The other electrode of the storage capacitor Cst may be connected to the driving voltage line PL. One electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., cathode) of the organic light-emitting diode OLED is supplied with a second power voltage ELVSS (or common power voltage). The organic light-emitting diode OLED receives the driving current from the driving thin-film transistor T1 and emits light.

The number of thin-film transistors and storage capacitors and the circuit design of the pixel circuit PC is not limited to those described above with reference to FIGS. 2A and 2B, and the number and circuit design may be variously changed. In an alternative embodiment, the pixel circuit PC may include three thin-film transistors and storage capacitors.

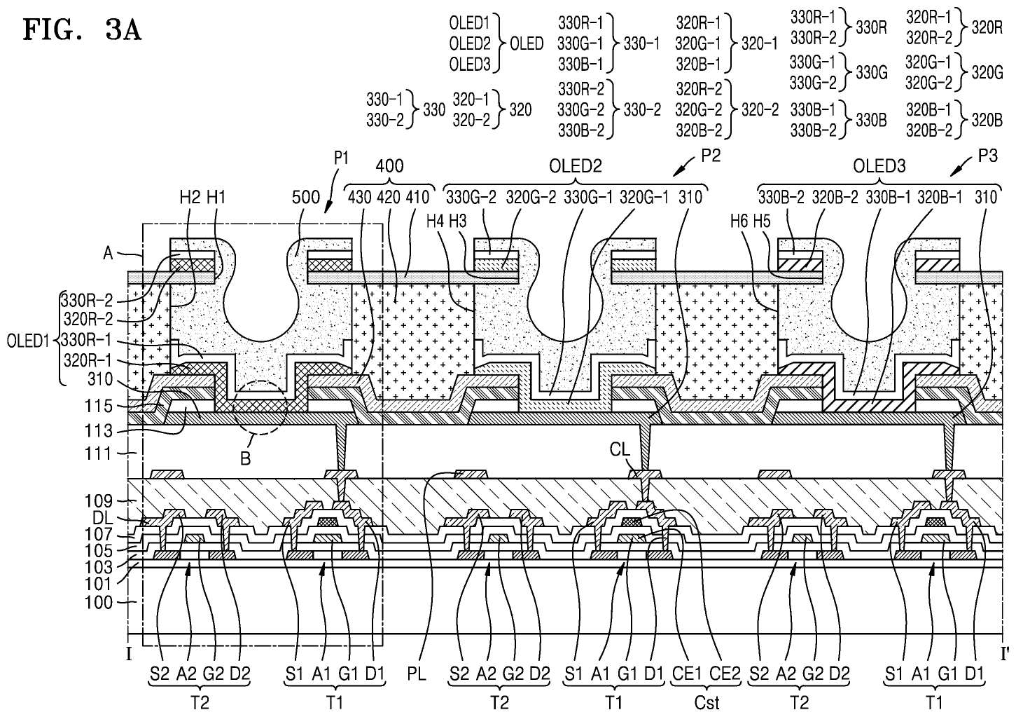

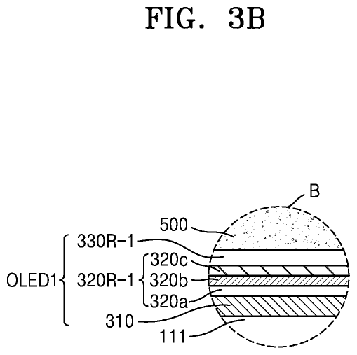

FIG. 3A is a schematic cross-sectional view of the display device of FIG. 1 taken along line I-I′, and FIG. 3B is an enlarged view of the encircled portion B of FIG. 3A.

Referring to FIG. 3A, the display device may include a driving thin-film transistor T1, a switching thin-film transistor T2, a storage capacitor CST, and an organic light-emitting diode OLED for each pixel. In an embodiment, a buffer layer 101 may be disposed on a substrate 100, and a driving thin-film transistor T1, a switching thin-film transistor T2, and a storage capacitor Cst may be disposed on the buffer layer 101.

The substrate 100 may include various materials such as a glass, metal, or plastic. In an embodiment, for example, the substrate 100 may be a flexible substrate including polymer resin such as polyethersulfone (PES), polyacrylate, polyetherimide (PEI), polyethylene naphthalate (PEN), polyethyeleneterepthalate (PET), polyphenylene sulfide (PPS), polyarylate (PAR), polyimide (PI), polycarbonate (PC), or cellulose acetate propionate (CAP).

The buffer layer 101, including silicon oxide (SiOx) and/or silicon nitride (SiNx) to prevent impurities from penetrating, may be disposed on the substrate 100.

The driving thin-film transistor T1 may include a driving semiconductor layer A1 and a driving gate electrode G1, and the switching thin-film transistor T2 may include a switching semiconductor layer A2 and a switching gate electrode G2. A first gate insulating layer 103 may be arranged between the driving semiconductor layer A1 and the driving gate electrode G1, and between the switching semiconductor layer A2 and the switching gate electrode G2. The first gate insulating layer 103 may include an inorganic insulating material such as silicon oxide (SiOx), silicon nitride (SiNx), or silicon oxynitride (SiON).

In an embodiment, the driving semiconductor layer A1 and the switching semiconductor layer A2 may include an amorphous silicon or a polycrystalline silicone. In an alternative embodiment, the driving semiconductor layer A1 and the switching semiconductor layer A2 may include oxide of at least one material selected from indium (In), gallium (Ga), tin (Sn), zirconium (Zr), vanadium (V), hafnium (Hf), cadmium (Cd), germanium (Ge), chromium (Cr), titanium (TI), and zinc (Zn).

The driving semiconductor layer A1 may include a driving channel area that overlaps the driving gate electrode G1 and is not doped with impurities, and a driving source area and a driving drain area arranged in both sides of the driving channel area and doped with impurities. The driving source area and the driving drain area may be connected to the driving source electrode S1 and the driving drain electrode D1, respectively.

The switching semiconductor layer A2 may include a switching channel area that overlaps the switching gate electrode G2 and is not doped with impurities, and a switching source area and a switching drain area arranged in opposing sides of the switching channel area and doped with impurities. The switching source area and the switching drain area may be connected to the switching source electrode S2 and the switching drain electrode D2, respectively.

Each of the driving gate electrode G1 and the switching gate electrode G2 may include molybdenum (Mo), aluminum (Al), copper (Cu), titanium (Ti), or the like and may be defined by a single layer or multiple layers.

In some embodiments, the storage capacitor Cst may overlap the driving thin-film transistor T1. In such embodiments, the area of the storage capacitor Cst and the driving thin-film transistor T1 may increase, and a high quality image may be provided. In an embodiment, for example, the driving gate electrode G1 may be a first storage capacitor board CE1 of the storage capacitor Cst. A second storage capacitor board CE2 may overlap the first storage capacitor board CE1 while a second gate insulating layer 105 is arranged between the second storage capacitor board CE2 and the first storage capacitor board CE1. The second gate insulating layer 105 may include an inorganic insulating material such as SiOx, SiNx, or SiON.

The driving thin-film transistor T1, the switching thin-film transistor T2, and the storage capacitor Cst may be covered with an interlayer insulating layer 107.

The interlayer insulating layer 107 may be an inorganic layer including an inorganic material such as SiON, SiOx, and/or SiNx.

The data line DL may be disposed on the interlayer insulating layer 107, and may be connected to the switching semiconductor layer A2 of the switching thin-film transistor T2 through a contact hole defined in the interlayer insulating layer 107. The data wire DL may serve as the switching source electrode S2.

The driving source electrode S1, the driving drain electrode D1, the switching source electrode S2, and the switching drain electrode D2 may be disposed on the interlayer insulating layer 107, and may be connected to the driving semiconductor layer A1 or the switching semiconductor layer A2 through a contact hole defined in the first gate insulating layer 103, the second gate insulating layer 105 and the interlayer insulating layer 107.

The data line DL, the driving source electrode S1, the driving drain electrode D1, the switching source electrode S2, and the switching drain electrode D2 may be covered with a first planarization layer 109.

The driving voltage line PL and the data line DL may be disposed in or directly on different layers from each other. In the disclosure, “A and B are disposed in different layers from each other” refers to a case in which at least one insulating layer is arranged between A and B, and one of A and B is disposed under the at least one insulating layer and the other of A and B is disposed on the at least one insulating layer. The first planarization layer 109 may be arranged between the driving voltage line PL and the data wire DL, and the driving voltage line PL may be covered with a second planarization layer 111.

The driving voltage line PL may be defined by a single layer or multiple layers, each layer therein including at least one selected from aluminum (Al), copper (Cu), titanium (Ti), and an alloy thereof. In an embodiment, the driving voltage line PL may be a three-layered film of Ti/Al/Ti.

FIG. 3A shows an embodiment having a configuration in which the driving voltage line PL is disposed on the first planarization layer 109, but the disclosure is not limited thereto. In an alternative embodiment, the driving voltage line PL may be connected to a lower additional voltage line (not shown) formed in a same layer as the layer on which the data line DL is formed through a through hole (not shown) formed in the first planarization layer 109, thereby decreasing resistance.

The first planarization layer 109 and the second planarization layer 111 may be formed as or defined by a single layer or multiple layers.

The first planarization layer 109 and the second planarization layer 111 may include an organic insulating material. In an embodiment, for example, the organic insulating material may include an imide-based polymer, a general-purpose polymer such as polymethylmethacrylate (PMMA) or polystylene (PS), a polymer derivative having a phenol-based group, an acryl-based polymer, an arylether-based polymer, an amide-based polymer, a fluorine-based polymer, a p-xylene-based polymer, or a vinyl alcohol-based polymer.

The first planarization layer 109 and the second planarization layer 111 may include an inorganic insulating material. In an embodiment, for example, the inorganic insulating material may include SiON, SiOx, SiNx, or the like.

A sub-pixel electrode 310 (or first electrode), an opposite electrode 330 (or second electrode), and an organic light-emitting diode OLED including an intermediate layer 320 arranged between the sub-pixel electrode 310 and the opposite electrode 330 and including an emission layer 320b may be disposed on the second planarization layer 111. The organic light-emitting diode OLED may include a first organic light-emitting diode OLED1 that emits red light, a second organic light-emitting diode OLED2 that emits green light, and a third organic light-emitting diode OLED3 that emits blue light.

The sub-pixel electrode 310 is connected to a connection line CL disposed on the first planarization layer 109, and the connection line CL is connected to the driving drain electrode D1 of the driving thin-film transistor T1.

The sub-pixel electrode 310 may be a transparent electrode or a reflective electrode.

In an embodiment where the sub-pixel electrode 310 is a transparent electrode, the sub-pixel electrode 310 may include a transparent conductive layer. The transparent conductive layer may include at least one selected from indium tin oxide (ITO), indium zinc oxide (IZO), zinc oxide (ZnO), indium oxide (In₂O₃), indium gallium oxide (IGO), and aluminum zinc oxide (AZO). In such an embodiment, the sub-pixel electrode 310 may further include a semi-transmissive layer to improve light efficiency in addition to the transparent conductive layer, and the semi-transmissive layer may include or be formed of a thin-film having a thickness of several to tens of micrometers (pm), and may include at least one selected from silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and ytterbium (Yb).

In an embodiment where the sub-pixel electrode 310 is a reflective electrode, the sub-pixel electrode 310 may include a reflective layer including Ag, Mg, Al, Pt, Pd, Au, Ni, Nd, Ir, Cr, or compounds thereof, and a transparent conductive layer arranged above and/or below the reflective layer. The transparent conductive layer may include at least one selected from ITO, IZO, ZnO, In₂O₃, IGO, and AZO.

However, the disclosure is not limited thereto, and the sub-pixel electrode 310 may be formed of various materials, and may have a single layer or multilayer structure according to various modifications.

A first insulating layer 115 may be arranged over the sub-pixel electrode 310.

The first insulating layer 115 may define an emission area of the organic light-emitting diode OLED by an opening defined therethrough to expose the sub-pixel electrode 310. Although the “opening” may include a through hole and a blind hole, hereinafter, the “opening” may refer to a through hole. The first insulating layer 115 may overlap the edge of the sub-pixel electrode 310. That is, the first insulating layer 115 may not be arranged in the emission area of the organic light-emitting diode OLED. The first insulating layer 115 may cover the edge of the sub-pixel electrode 310 and extend to a non-pixel area. That is, the first insulating layer 115 may extend from the edge of the sub-pixel electrode 310 of the first sub-pixel P1 through the non-pixel area to the edge of the sub-pixel electrode 310 of the second sub-pixel P2. Alternatively, the first insulating layer 115 may extend from the edge of the sub-pixel electrode 310 of the second sub-pixel P2 through the non-pixel area to the edge of the sub-pixel electrode 310 of the third sub-pixel P3.

The first insulating layer 115 may include an inorganic insulating material. In an embodiment, for example, the inorganic insulating material may include SiON, SiOx, SiNx, or the like. However, the disclosure is not limited thereto, and the first insulating layer 115 may include an organic insulating material. In an embodiment, for example, the organic insulating material may be a commercial polymer such as polymethyl methacrylate (PMMA) or polystyrene (PS), a polymer derivative having a phenol-based group, an acryl-based polymer, an arylether-based polymer, an amide-based polymer, a fluorine-based polymer, a p-xylene-based polymer, or a vinyl alcohol-based polymer. In an embodiment where the first insulating layer 115 includes an inorganic insulating material, outgassing from an organic material may be prevented, thereby improving a lifespan of the organic light-emitting diode OLED.

A first protective layer 113 may be arranged between the sub-pixel electrode 310 and the first insulating layer 115. The first protective layer 113 may protect the sub-pixel electrode 310 from damages that may occur in the process of forming holes in the metal stacked structure 400 and the first insulating layer 115 to be described later. Accordingly, a lower surface of the first protective layer 113 may contact the sub-pixel electrode 310, and an upper surface of the first protective layer 113 may contact the first insulating layer 115. In addition, as in the first insulating layer 115, the first protective layer 113 may define the emission area of the organic light-emitting diode OLED by including an opening defined therethrough to expose the sub-pixel electrode 310. That is, the first protective layer 113 may also be arranged at the edge of the sub-pixel electrode 310 without being arranged in the emission area of the organic light-emitting diode OLED.

The first protective layer 113 may include a transparent conductive oxide (TCO). in an embodiment, the TCO of the first protective layer 113 may include at least one selected from ITO, IZO, ZnO, In₂O₃, IGO, and AZO.

In the non-pixel area, a metal stacked structure 400 including a plurality of sub-metal layers may be disposed on the first insulating layer 115. The metal stacked structure 400 may be electrically connected to a power voltage line surrounding a portion of the display area DA (FIG. 1) to provide a second power voltage ELVSS (or common power voltage, FIGS. 2A and 2B). Accordingly, in an embodiment, the metal stacked structure 400 may be arranged in a planar mesh pattern. In such an embodiment, the metal stacked structure 400 may surround each of the sub-pixels, for example, the first to third sub-pixels P1, P2, and P3 in a plan view.

The metal stacked structure 400 may include a first sub-metal layer 410, and a second sub-metal layer 420 disposed under the first sub-metal layer 410. Alternatively, the metal stacked structure 400 may further include a third sub-metal layer 430 disposed under the second sub-metal layer 420, in addition to the first sub-metal layer 410 and the second sub-metal layer 420. However, the third sub-metal layer 430 is not necessarily included, and the second sub-metal layer 420 may be directly disposed on the first insulating layer 115.

The plurality of sub-metal layers included in the metal stacked structure 400 may have different etching ratios from each other. In an embodiment, the first sub-metal layer 410 and the third sub-metal layer 430 may include a same material as each other, but the first sub-metal layer 410 and the second sub-metal layer 420 may include materials having different etching ratios from each other. In an embodiment, the first sub-metal layer 410 and the third sub-metal layer 430 may be a metal layer including Ti, and the second sub-metal layer 420 may be a metal layer including Al. In such an embodiment, the metal stacked structure 400 may be a structure in which a third sub-metal layer 430 including Ti, a second sub-metal layer 420 including Al, and a first sub-metal layer 410 including Ti are sequentially stacked.

As in the first insulating layer 115 and the first protective layer 113, the metal stacked structure 400 may define an opening that exposes the sub-pixel electrode 310. The metal stacked structure 400 may not be arranged in the emission area of the organic light-emitting diode OLED. in an embodiment, the first sub-metal layer 410 may define a first hole H1 corresponding to the emission area of the organic light-emitting diode OLED, and the third sub-metal layer 430 may also define a hole having substantially the same diameter as the hole of the first sub-metal layer 410. The diameter of the first hole H1 of the first sub-metal layer 410 may be substantially the same as or similar to the diameter of the hole included in the first insulating layer 115. In an embodiment, as described above, the first sub-metal layer 410 and the second sub-metal layer 420 may include materials having different etching ratios from each other, such that the second sub-metal layer 420 may define a second hole H2 overlapping the first hole H1 of the first sub-metal layer 410 but having a greater diameter than the first hole H1. The edge of the first sub-metal layer 410 defining the first hole H1 may form an undercut structure in which the edge of the first sub-metal layer 410 protrudes more toward the center of the first hole H1 than the edge of the second sub-metal layer 420 defining the second hole H2. That is, because the second sub-metal layer 420 is etched more than the first sub-metal layer 410 in the metal stacked structure 400, a portion of the first sub-metal layer 410 may form a tip by being protruded more than a side surface of the second sub-metal layer 420. The length of the tip of the first sub-metal layer 410, that is, the length from a point where the side surface of the second sub-metal layer 420 and the bottom surface of the first sub-metal layer 410 meet to the edge of the first sub-metal layer 410 (or side surface) may be about 2 μm or less. In some embodiments, the length of the tip of the first sub-metal layer 410 may be in a range of about 0.3 μm to about 1 μm, or in a range of about 0.3 μm to about 0.7 μm.

A third hole H3 and a fifth hole H5 may be in the second sub-pixel P2 and the third sub-pixel P3, respectively, to correspond to the first hole H1 of the first sub-pixel P1, and a fourth hole H4 and a sixth hole H6 may be formed or defined in the second sub-pixel P2 and the third sub-pixel P3, respectively, to correspond to the second hole H2 of the first sub-pixel P1. Although the first hole H1 and the second hole H2 were described for convenience of description, the third hole H3 and the fifth hole H5 have the same characteristics as those of the first hole H1, and the fourth hole H4 and the sixth hole H6 have the same characteristics as those of the second hole H2.

The intermediate layer 320 may be disposed on the sub-pixel electrode 310. The intermediate layer 320 may be separated (or disconnected) individually in the plurality of organic light-emitting diodes OLED and may correspond to the plurality of sub-pixel electrodes 310. The intermediate layer 320 may include a first intermediate layer 320R arranged in the first sub-pixel P1 for emitting red light, a second intermediate layer 320G arranged in the second sub-pixel P2 for emitting green light, and a third intermediate layer 320B arranged in the third sub-pixel P3 for emitting blue light. In such an embodiment, the first intermediate layer 320R may include a first portion of the first intermediate layer 320R-1 and a second portion of the first intermediate layer 320R-2, the second intermediate layer 320G may include a first portion of the second intermediate layer 320G-1 and a second portion of the second intermediate layer 320G-2, and the third intermediate layer 320B may include a first portion of the third intermediate layer 320B-1 and a second portion of the third intermediate layer 320B-2. In addition, each intermediate layer 320 may include the emission layer 320b. In an embodiment, as shown in FIG. 3B, the intermediate layer 320 may include a first functional layer 320a disposed under the emission layer 320b and/or a second functional layer 320c disposed on the emission layer 320b. The emission layer 320b may include a polymer or a small molecular weight organic material that emits light of a certain color.

The first functional layer 320a may be a single layer or multiple layers. In an embodiment, for example, where the first functional layer 320a include or is formed of a polymer material, the first functional layer 320a may be a hole transport layer (HTL) having a single-layer structure and may include or be formed of poly-(3,4)-ethylene-dihydroxy thiophene (PEDOT) or polyaniline (PANI). In an embodiment, for example, where the first functional layer 320a include or is formed of a low-molecular weight material, the first functional layer 320a may include a hole injection layer (HIL) and an HTL.

In an alternative embodiment, the second functional layer 320c may be omitted. In an embodiment, for example, where the first functional layer 320a and the emission layer 320b include or are formed of a polymer material, the second functional layer 320c may be provided. The second functional layer 320c may be a single layer or multiple layers. The second functional layer 320c may include an electron transport layer (ETL) and/or an electron injection layer (EIL).

The emission layer 320b of the intermediate layer 320 may be arranged in each of the sub-pixels P in the display area DA. The organic emission layer 320b of each of the first sub-pixel P1, the second sub-pixel P2, and the third sub-pixel P3 may emit light of different colors from each other. The emission layer 320b may be formed on the sub-pixel electrode 310 exposed through the opening of the first insulating layer 115. The intermediate layer 320 may be formed in various methods such as vacuum deposition.

The opposite electrode 330 may be disposed on the intermediate layer 320. As in the intermediate layer 320, the opposite electrode 330 may be separated individually in the plurality of organic light-emitting diodes OLED to correspond to the plurality of sub-pixel electrodes 310. In an embodiment, the opposite electrode 330 may include a first opposite electrode 330R arranged in the first sub-pixel P1, a second opposite electrode 330G arranged in the second sub-pixel P2, and a third opposite electrode 330B arranged in the third sub-pixel P3. In such an embodiment, the first opposite electrode 330R may include a first portion of the first opposite electrode 330R-1 and a second portion of the first opposite electrode 330R-2, which are separated and apart from each other, the second opposite electrode 330G may include a first portion of the second opposite electrode 330G-1 and a second portion of the second opposite electrode 330G-2, which are separated and apart from each other, and the third opposite electrode 330B may include a first portion of the third opposite electrode 330B-1 and a second portion of the third opposite electrode 330B-2, which are separated and apart from each other.

The opposite electrode 330 may be a transparent electrode or a reflective electrode. In an embodiment where the opposite electrode 330 is a transparent electrode, the opposite electrode 330 may include at least one material selected from Ag, Al, Mg, Li, Ca, Cu, LiF/Ca, LiF/Al, MgAg, and CaAg, and may be formed in the form of a thin-film having a thickness of several to tens of micrometers (μm).

In an embodiment where the opposite electrode 330 is a reflective electrode, the opposite electrode 330 may include at least one material selected from a group including Ag, Al, Mg, Li, Ca, Cu, LiF/Ca, LiF/AI, MgAg, and CaAg. The configuration and materials of the opposite electrode 330 are not limited thereto, and various modifications are possible.

In an embodiment, the first hole H1 and the second hole H2 of the metal stacked structure 400 may be formed before a process of forming the intermediate layer 320 and the opposite electrode 330 of the organic light-emitting diode OLED. That is, the intermediate layer 320 and the opposite electrode 330 of the organic light-emitting diode OLED may be separated by an undercut structure of the metal stacked structure 400. The intermediate layer 320 and the opposite electrode 330 may be disconnected by the first hole H1 and the second hole H2 of the metal stacked structure 400. In an embodiment, the intermediate layer 320 may include a first portion of the intermediate layer 320-1 and a second portion of the intermediate layer 320-2, the first portion of the intermediate layer 320-1 may be disposed on the sub-pixel electrode 310 in areas of the first hole H1 and the second hole H2, and the second portion of the intermediate layer 320-2 may be disposed on the metal stacked structure 400. In such an embodiment, the opposite electrode 330 may include a first portion of the opposite electrode 330-1 and a second portion of the opposite electrode 330-2, the first portion of the opposite electrode 330-1 may be disposed on the first portion of the intermediate layer 320-1 in areas of the first hole H1 and the second hole H2, and the second portion of the opposite electrode 330-2 may be disposed on the second portion of the intermediate layer 320-2. That is, the first portion 320-1 of the intermediate layer and the first portion 330-1 of the opposite electrode may remain at the lower surface of the first hole H1 and the second hole H2, and the second portion of the intermediate layers 320-2 and the second portion of the opposite electrodes 330-2 may each be apart from each other with respect to the first hole H1 and the second hole H2 and disposed on the metal stacked structure 400. However, the second portion of the intermediate layer 320-2 and the second portion of the opposite electrode 330-2 do not extend to the non-pixel area, and may not be arranged in the non-pixel area as shown in FIG. 3A. In an embodiment, the second portion of the intermediate layer 320-2 and the second portion of the opposite electrode 330-2 may not be disposed on the second sub-metal layer 420 of the metal stacked structure 400. That is, the second portion of the intermediate layer 320-2 and the second portion of the opposite electrode 330-2 may be arranged only in the pixel area of the first sub-pixel P1, the second sub-pixel P2, and the third sub-pixel P3.

The first portion of the opposite electrode 330-1 arranged in the first hole H1 and the second hole H2 may be in contact with the side surface of the second sub-metal layer 420 of the metal stacked structure 400. That is, the first portion of the opposite electrode 330-1 may be electrically connected to the metal stacked structure 400. In such an embodiment, as described above, because the metal stacked structure 400 may be electrically connected to the power voltage line to provide a second power voltage ELVSS (or a common power voltage), the first portion of the opposite electrode 330-1 may be provided with the second power voltage line ELVSS.

In an embodiment, because the second sub-metal layer 420 of the metal stacked structure 400 has a structure with a hole having a greater diameter than that of the first sub-metal layer 410, the thickness of the second sub-metal layer 420 is desired to be secured sufficiently so that the first portion of the opposite electrode 330-1 may be in contact with the second sub-metal layer 420 of the metal stacked structure 400. That is, the greater the height of the metal stacked structure 400, the greater the thickness of the second sub-metal layer 420. In an embodiment, the thickness of the second sub-metal layer 420 may be greater than 1/2 of the height of the metal stacked structure 400, when determined based on an incident angle of the intermediate layer 320 and the opposite electrode 330. In an embodiment, where the height of the metal stacked structure 400 is about 0.5 μm, the thickness of the second sub-metal layer 420 may be at least about 0.29 μm. However, embodiments are not limited thereto, and the thickness of the second sub-metal layer 420 may be freely determined as long as the first portion of the opposite electrode 330-1 is in contact with the second sub-metal layer 420.

Because the organic light-emitting diode OLED may be easily damaged by moisture or oxygen from the outside, a thin-film encapsulation layer 500 may cover and thereby protect the organic light-emitting diode OLED.

The thin-film encapsulation layer 500 may include at least one organic encapsulation layer and at least one inorganic encapsulation layer. In an embodiment, the thin-film encapsulation layer 500 may include a first inorganic encapsulation layer, an organic encapsulation layer, and a second inorganic encapsulation layer. In an embodiment where the inorganic encapsulation layer is formed along a lower structure, and the organic encapsulation layer is arranged to planarize the upper surface of the lower structure, the organic encapsulation layer may be omitted. Thus, embodiments are not limited thereto, and the thin-film encapsulation layer 500 may include at least one inorganic encapsulation layer only. In such an embodiment, the inorganic encapsulation layer may include silicon oxide, silicon nitride, and/or silicon oxynitride, and the organic encapsulation layer may include polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, etc.), or any combination thereof.

Because the thin-film encapsulation layer 500 is desired to protect the organic light-emitting diode OLED, the thin-film encapsulation layer 500 may fill the first hole H1 and the second hole H2 of the metal stacked structure 400 to cover the organic light-emitting diode OLED. In addition, the thin-film encapsulation layer 500 may cover the second portion of the intermediate layer 320-2 and the second portion of the opposite electrode 330-2, both disposed on the metal stacked structure 400. The thin-film encapsulation layer 500 does not extend to the non-pixel area as shown in FIG. 3A, and may not be arranged in the non-pixel area. In an embodiment, the thin-film encapsulation layer 500 may not be arranged over the second sub-metal layer 420 of the metal stacked structure 400. That is, the thin-film encapsulation layer 500 may be arranged only in the pixel area of the first sub-pixel P1, the second sub-pixel P2, and the third sub-pixel P3, thereby forming a sealed structure for each sub-pixel unit.

The display device according to an embodiment may improve the resolution of the display device through the structure as described above and implement an image of high quality. In the prior art, because the organic light-emitting diode OLED is formed by using a fine metal mask (FMM), a bank layer and a spacer for supporting the FMM are used. However, in the case of the prior art, the improvement of resolution may be limited due to gaps caused by the FMM, and organic particles may be generated due to the spacer being imprinted on the FMM, thereby causing defects. In an embodiment, the bank layer and the spacer may be removed from the display device, and the resolution may be improved, and organic particle defects caused by the FMM contact may decrease by forming the organic light-emitting diode OLED by using an open mask without the FMM. In such an embodiment, because the intermediate layer 320 and the opposite electrode 330 are each disconnected by the metal stacked structure 400, lateral leakage current that has previously occurred along the upper common layer of the bank layer may not occur. In such an embodiment, because the first portion of the opposite electrode 330-1 is electrically connected to the second sub-metal layer 420 of the metal stacked structure 400, the second sub-metal layer 420 may be thicker than the wiring to which the second power voltage is supplied, thereby reducing driving resistance. In such an embodiment, even if defects such as dark spots occur, because the intermediate layer 320 and the opposite electrode 330 are each disconnected by the metal stacked structure 400 and the thin-film encapsulation layer 500 seals each sub-pixel, inhibiting growth of the dark spot may be implemented at the same time.

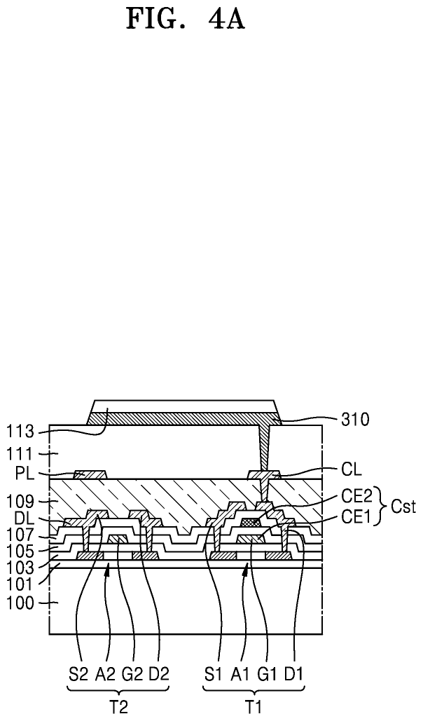

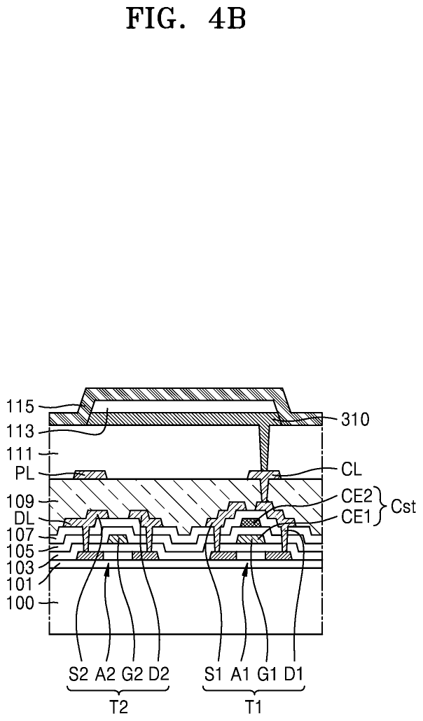

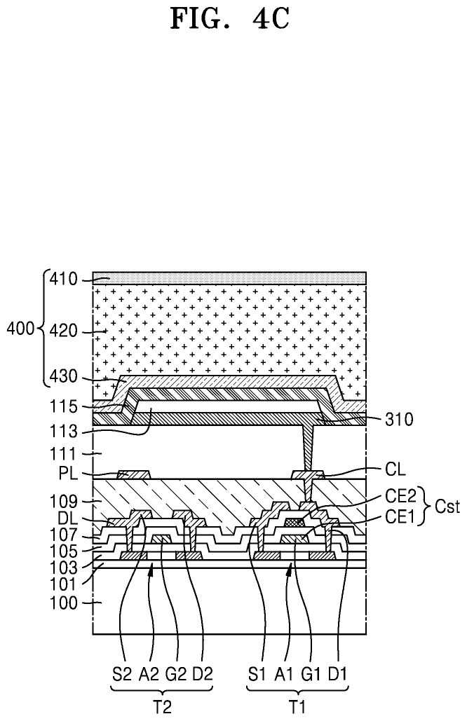

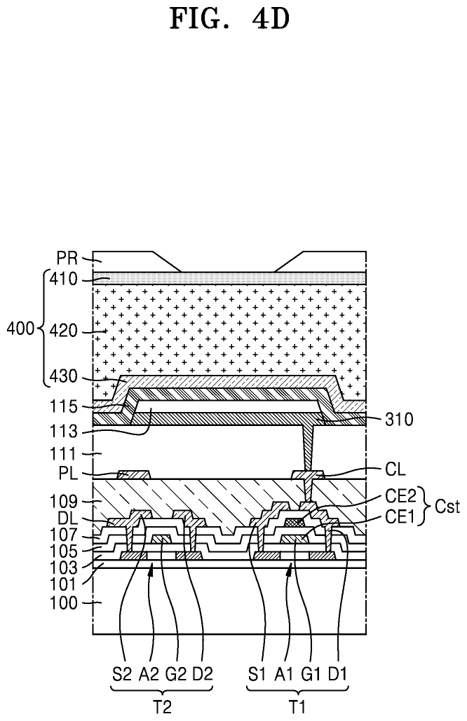

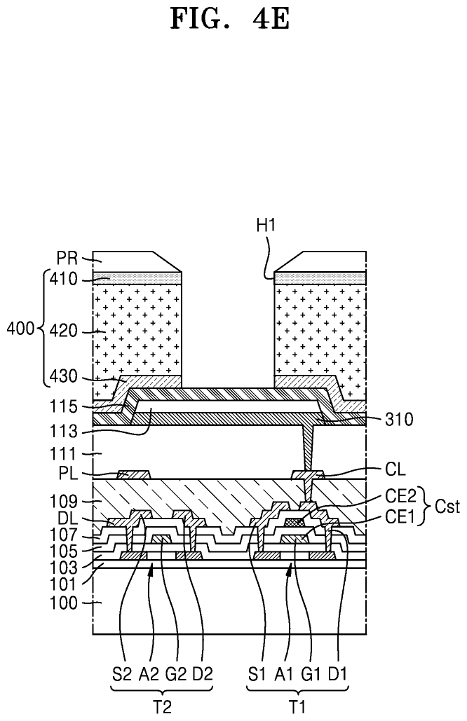

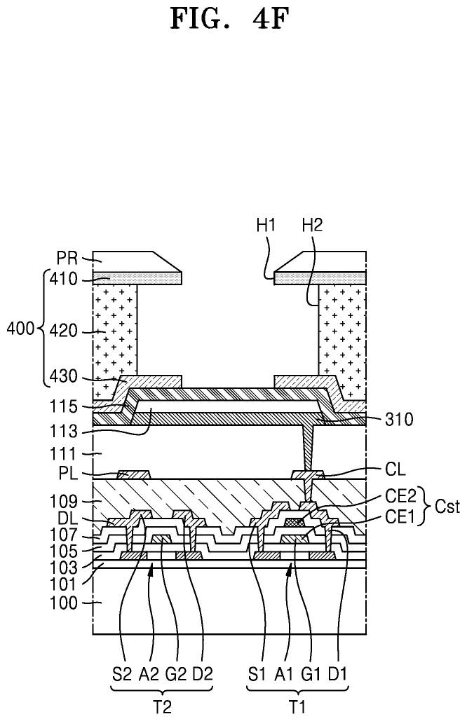

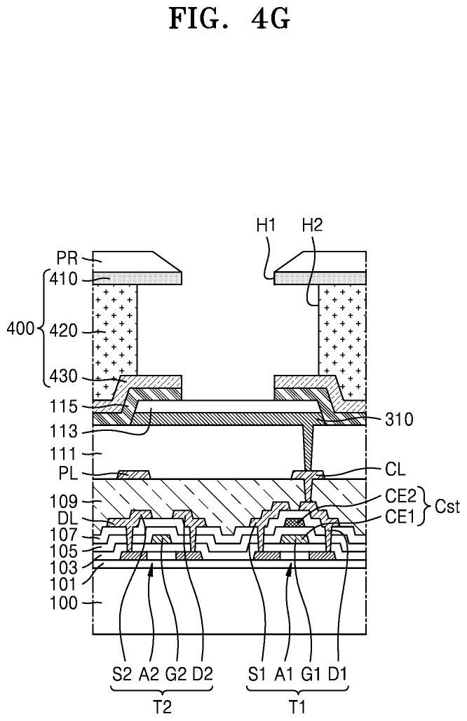

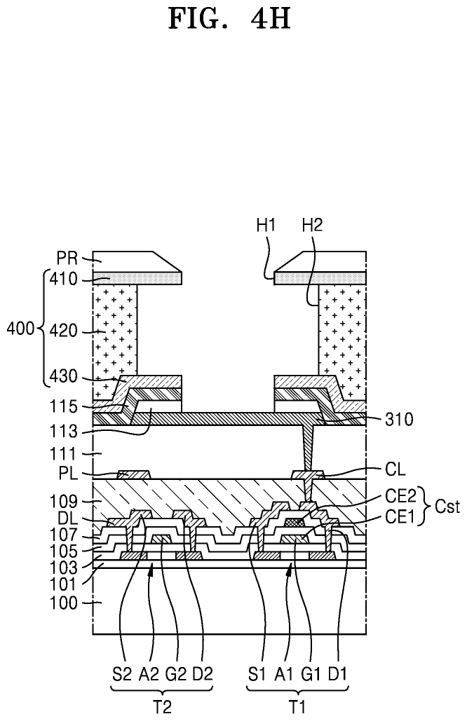

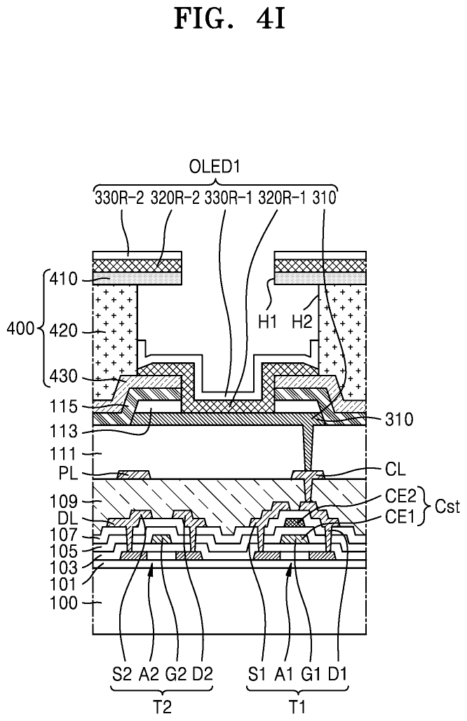

FIGS. 4A to 4I are cross-sectional views sequentially illustrating a process of manufacturing a display device according to an embodiment. FIGS. 4A to 4I may correspond to the encircled portion A of FIG. 3A. That is, FIGS. 4A to 4I are cross-sectional views of the pixel area of the first sub-pixel P1 of the display device according to an embodiment, and the manufacturing process thereof may apply to the second sub-pixel P2 and the third sub-pixel P3.

In an embodiment, as shown in FIG. 4A, the driving thin-film transistor T1, the switching thin-film transistor T2, and the storage capacitor Cst may be provided to be covered with the first planarization layer 109 and the second planarization layer 111, and the sub-pixel electrode 310 may be formed on the second planarization layer 111. The first planarization layer 109 and the second planarization layer 111 may be provided across the display area DA and the non-display area NDA, and the sub-pixel electrode 310 may be provided in the sub-pixels arranged in the display area DA. Subsequently, first protective layer 113 may be provided over the sub-pixel electrode 310. In an embodiment, the first protective layer 113 may be formed such that the first protective layer 113 does not deviate from the area in which the sub-pixel electrode 310 is arranged. In such an embodiment, the first protective layer 113 may include a transparent conductive oxide.

Next, as shown in FIG. 4B, the first insulating layer 115 may be provided on the sub-pixel electrode 310 and the first protective layer 113. The first insulating layer 115 may not only be arranged in the pixel are of the plurality of sub-pixels, but also cover the edge of the sub-pixel and extend to the non-pixel area. That is, the first insulating layer 115 may be formed in the entire area of the display area DA. In such an embodiment, the first insulating layer 115 may include an inorganic insulating material.

Next, as shown in FIG. 4C, the metal stacked structure 400 may be provided over the first insulating layer 115. The metal stacked structure 400 includes the first sub-metal layer 410, the second sub-metal layer 420, and the third sub-metal layer 430, and the third sub-metal layer 430, the second sub-metal layer 420, and the first sub-metal layer 410 may subsequentially be provided or stacked on the first insulating layer 115. In such an embodiment, the first sub-metal layer 410 and the second sub-metal layer 420 may include materials having different etching ratios from each other, and the first sub-metal layer 410 and the third sub-metal layer 430 may include a same material as each other. In an embodiment, for example, the metal stacked structure 400 may include a Ti/Al/Ti structure.

Next, as shown in FIG. 4D, a photoresist layer PR may be provided over the metal stacked structure 400. The photoresist layer PR may include an opening that corresponds to the position where the first hole H1 and the second hole H2 are to be formed. That is, the opening of the photoresist layer PR may overlap the emission area of the plurality of sub-pixels.

Next, as shown in FIG. 4E, the first hole H1 corresponding to the opening of the photoresist layer PR may be formed in the metal stacked structure 400 by using the photoresist layer PR as a mask. The photoresist layer PR may remain until the forming of the first hole H1 is completed, while functioning as a patterning mask.

In the process in which the first hole H1 of the first sub-metal layer 410 arranged in the top layer of the metal stacked structure 400 is formed, the second sub-metal layer 420 and the third sub-metal layer 430 disposed under the first sub-metal layer 410 may be removed. In an embodiment, for example, the second sub-metal layer 420 and the third sub-metal layer 430 may be removed together with the first sub-metal layer 410. The first sub-metal layer 410, the second sub-metal layer 420, and the third sub-metal layer 430 may be removed at once by using dry etching. In such an embodiment, the first hole H1, which has the same diameter as that of the opening of the photoresist layer PR, may be formed through the first sub-metal layer 410, the second sub-metal layer 420, and the third sub-metal layer 430.

Next, as shown in FIG. 4F, the second hole H2 overlapping the first hole H1 formed in the previous process may be formed in the second sub-metal layer 420 of the metal stacked structure 400. In this operation, the second hole H2 having a greater diameter than that of the first hole H1 of the first sub-metal layer 410 may be formed in the second sub-metal layer 420 to implement an undercut structure or an eave-like structure. The second hole H2 of the second sub-metal layer 420 may be removed at once by using wet etching. Because the first sub-metal layer 410 and the second sub-metal layer 420 include materials having different etching ratios from each other, the diameter of the second hole H2 of the second sub-metal layer 420 may be greater than the diameter of the first hole H1 of the first sub-metal layer 410. In an embodiment, for example, the first sub-metal layer 410 and the third sub-metal layer 430 including titanium Ti may be relatively less etched or not etched in the wet etching process, and thus, the second sub-metal layer 420 including aluminum Al may be relatively more etched. Because the diameter of the second hole H2 is greater than the diameter of the first hole H1, the edge of the first sub-metal layer 410 may protrude more toward the center of the first hole H1 than the edge of the second sub-metal layer 420 defining the second hole H2, thereby providing a tip shape.

Next, as shown in FIG. 4G, a hole corresponding to the opening of the photoresist layer PR may be formed in the first insulating layer 115 by using the photoresist layer PR as a mask. That is, the diameter of the hole of the first insulating layer 115 may be the same as the diameter of the first hole H1 of the first sub-metal layer 410 and the third sub-metal layer 430. In an embodiment, a portion of the first insulating layer 115 may be removed using dry etching to form the hole overlapping the first hole H1 in the first insulating layer 115.

Next, as shown in FIG. 4H, a hole corresponding to the opening of the photoresist layer PR may be formed in the first protective layer 113 by using the photoresist layer PR as a mask. The diameter of the hole of the first protective layer 113 may be substantially similar to or slightly greater than the diameter of the first hole H1 of the first sub-metal layer 410 and the third sub-metal layer 430. In an embodiment, a portion of the first protective layer 113 may be removed using wet etching to form the hole overlapping the first hole H1 in the first protective layer 113.

Then, as shown in FIG. 4I, the photoresist layer PR disposed on the first sub-metal layer 410 is removed. Subsequently, the intermediate layer 320 and the opposite electrode 330 may be sequentially provided or stacked in the process of forming the organic light-emitting diode OLED. In such an embodiment, the intermediate layer 320 and the opposite electrode 330 may be separated or disconnected by the undercut structure of the metal stacked structure 400. In an embodiment, for example, the first portion of the first intermediate layer 320R-1 and the first portion of the first opposite electrode 330R-1 may be formed in the first hole H1 and the second hole H2 of the metal stacked structure 400, and the second portion of the first intermediate layer 320R-2 and the second portion of the first opposite electrode 330R-2 may be formed over the metal stacked structure 400.

In an embodiment, referring to FIG. 4I, an opposite electrode 330 may be formed in a way such that the second portion of the first opposite electrode 330R-2 contacts the second sub-metal layer 420 of the metal stacked structure 400. In an embodiment, considering that the edge of the first sub-metal layer 410 is protruded toward the center more than the edge of the second sub-metal layer 420, a deposition angle of the first portion of the first intermediate layer 320R-1 and the first portion of the first opposite electrode 330-1 may be adjusted.

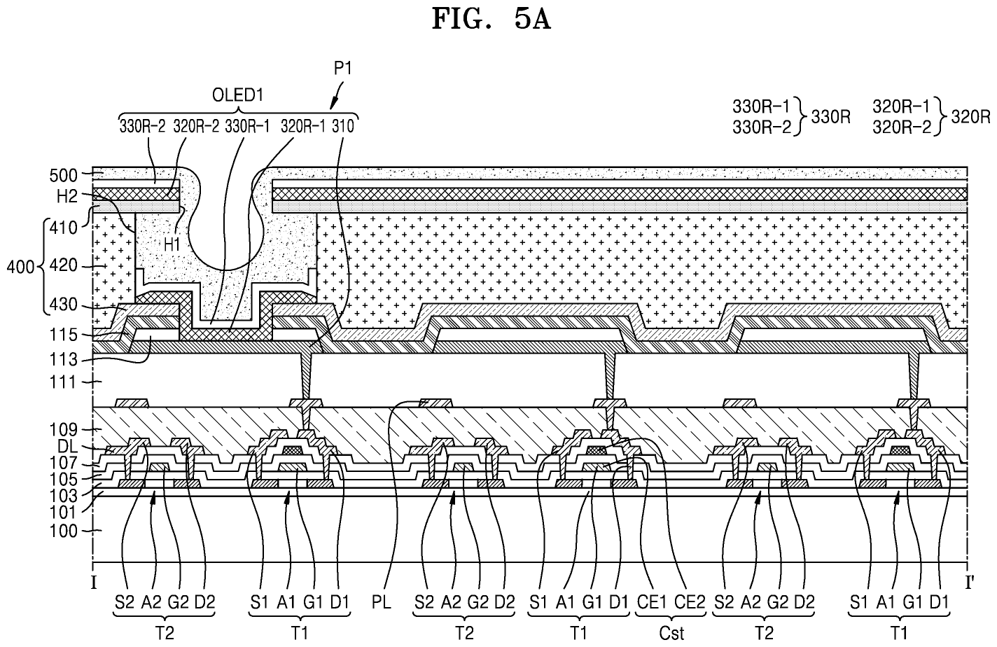

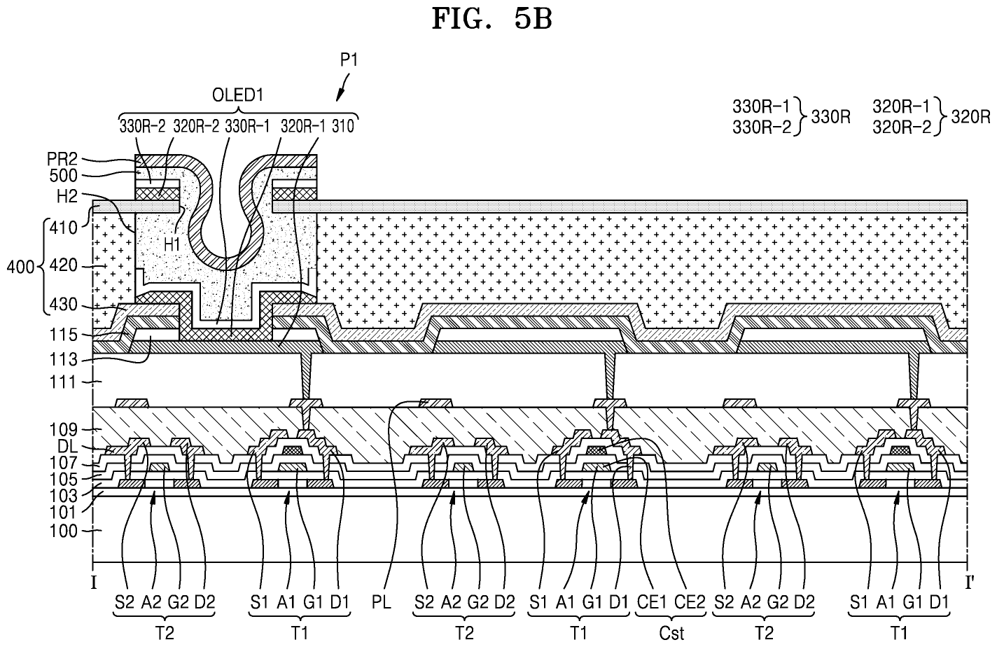

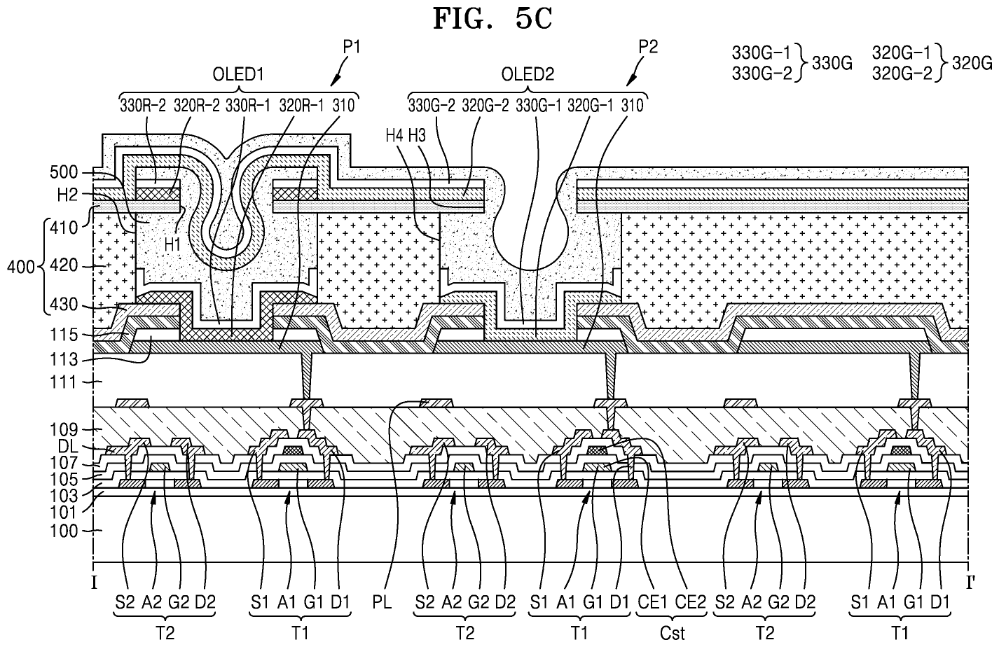

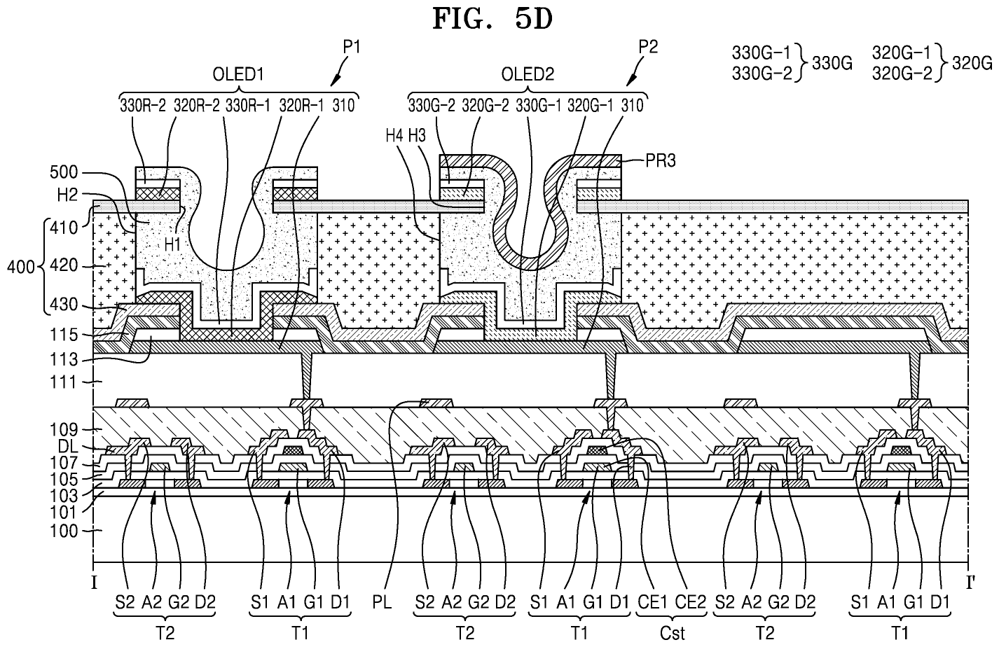

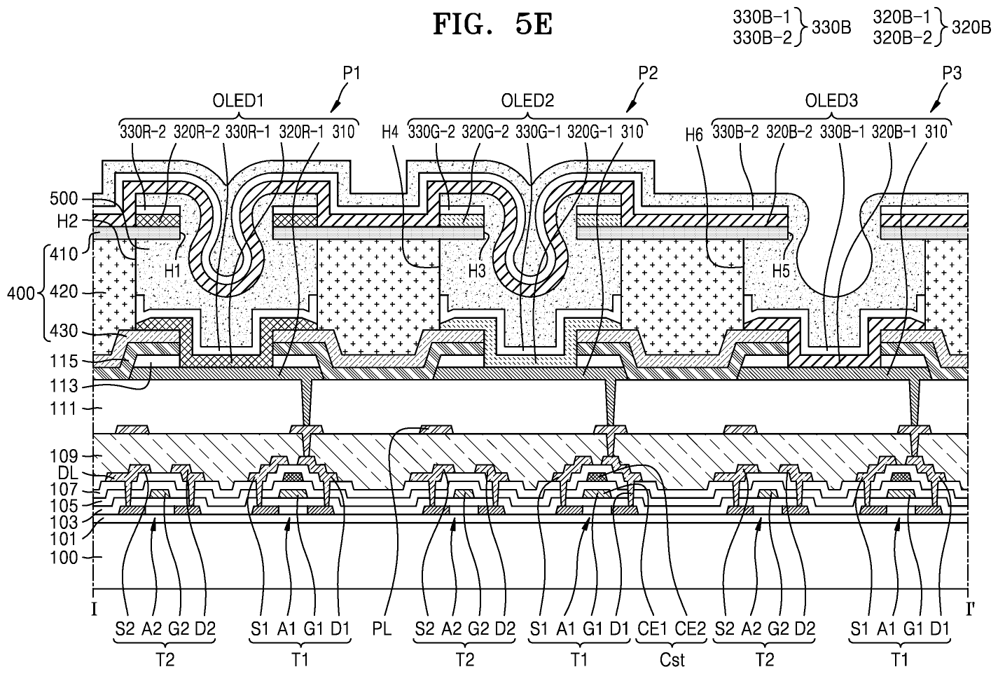

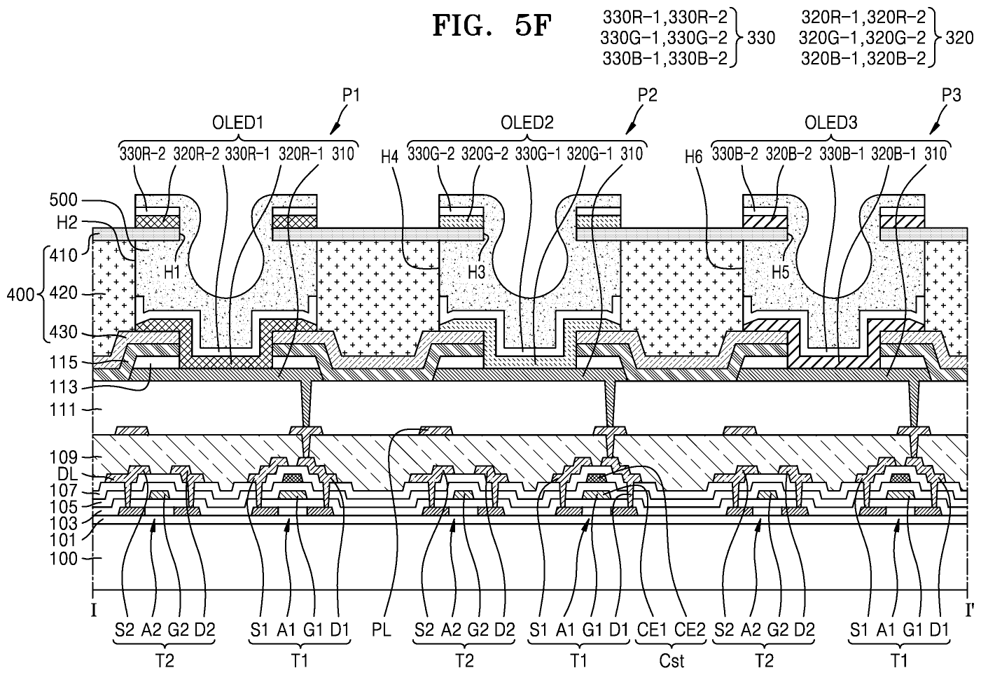

FIGS. 5A to 5F are cross-sectional views sequentially illustrating a process of manufacturing a display device according to an embodiment.

In an embodiment, referring to FIG. 5A, after the first intermediate layer 320R and the first opposite electrode 330R are formed over the first sub-pixel P1 of the display device as described above with reference to FIG. 4I, the thin-film encapsulation layer 500 may be provided or formed over the disconnected second portion of the first opposite electrode 330R-2. The thin-film encapsulation layer 500 may include at least one inorganic encapsulation layer only, but is not limited thereto, and alternatively, the thin-film encapsulation layer 500 may include at least one organic encapsulation layer and at least one inorganic encapsulation layer. As shown in FIG. 5A, a portion of the thin-film encapsulation layer 500 may fill the hole of the first protective layer 113, the hole of the first insulating layer 115, and the first hole H1 and the second hole H2 of the metal stacked structure 400. In the remaining areas excluding the first sub-pixel P1, the thin-film encapsulation layer 500 may be provided on the second portion of the first intermediate layer 320R-2 and the second portion of the first opposite electrode 330R-2.

Next, as shown in FIG. 5B, a second photoresist layer PR2 may be formed over the pixel area of the first sub-pixel P1. The second photoresist layer PR2 may be stacked on the thin-film encapsulation layer 500. The second photoresist layer PR2 may be patterned through an exposure and development process in a position corresponding to the pixel area of the first sub-pixel P1 by using a photomask. Thereafter, the second portion of the first intermediate layer 320R-2, the second portion of the first opposite electrode 330R-2, and a portion of the thin-film encapsulation layer 500 may be removed by using the patterned second photoresist layer PR2 as an etching mask. Portions of the second portion of the first intermediate layer 320R-2, the second portion of the first opposite electrode 330R-2, and the thin-film encapsulation layer 500, which are arranged in remaining areas excluding the pixel area of the first sub-pixel P1, may be removed at once by using dry etching. Accordingly, the second portion of the first intermediate layer 320R-2, the second portion of the first opposite electrode 330R-2, and the thin-film encapsulation layer 500 may be arranged only in the pixel area of the first sub-pixel P1. Opposing edges of the second portion of the first intermediate layer 320R-2, opposing edges of the first opposite electrode 330R-2, and opposing edges of the thin-film encapsulation layer 500, each corresponding to the pixel area of the first sub-pixel P1, may be located on substantially a same vertical line or be aligned with each other in a thickness direction of the display device.

Next, as shown in FIG. 5C, the second photoresist layer PR2 disposed over the pixel area of the first sub-pixel P1 may be removed. In addition, in the pixel area of the second sub-pixel P2, the manufacturing process performed in the first sub-pixel P1 may be repeated as in FIGS. 4D to 4I. In an embodiment, in the second sub-pixel P2, the third hole H3 corresponding to the first hole H1 and the second hole H2 corresponding to the fourth hole H4 may be formed in the metal stacked structure 400 to provide an undercut structure or a tip shape. Thereafter, the second intermediate layer 320G and the second opposite electrode 330G may be stacked on the second sub-pixel P2, and the second intermediate layer 320G and the second opposite electrode 330G may be disconnected by the undercut structure. Therefore, the first portion of the second intermediate layer 320G-1 and the first portion of the second opposite electrode 330G-1 may be arranged in the third hole H3 and the fourth hole H4, and the second portion of the second intermediate layer 320G-2 and the second portion of the second opposite electrode 330G-2 may be disposed over the metal stacked structure 400. Next, the thin-film encapsulation layer 500 may be formed as in FIG. 5A, and accordingly, a portion of the thin-film encapsulation layer 500 may fill the third hole H3 and the fourth hole H4, and the remaining portion of the thin-film encapsulation layer 500 may be disposed over the second portion of the second opposite electrode 330G-2.

Next, as shown in FIG. 5D, a third photoresist layer PR3 may be formed over the pixel area of the second sub-pixel P2. The third photoresist layer PR3 may be stacked on the thin-film encapsulation layer 500. The third photoresist layer PR3 may be patterned through an exposure and development process in a position corresponding to the pixel area of the second sub-pixel P2 by using a photomask. Thereafter, the second portion of the second intermediate layer 320G-2, the second portion of the second opposite electrode 330G-2, and a portion of the thin-film encapsulation layer 500 may be removed by using the patterned third photoresist layer PR2 as an etching mask. Portions of the second portion of the second intermediate layer 320G-2, the second portion of the second opposite electrode 330G-2, and the thin-film encapsulation layer 500, which are arranged in remaining areas excluding the pixel area of the second sub-pixel P2, may be removed at once by using dry etching. Accordingly, the second portion of the second intermediate layer 320G-2, the second portion of the second opposite electrode 330G-2, and the thin-film encapsulation layer 500 may be arranged only in the pixel area of the second sub-pixel P2.

Next, as shown in FIG. 5E, the third photoresist layer PR3 disposed over the pixel area of the second sub-pixel P2 may be removed. In addition, in the pixel area of the third sub-pixel P3, the manufacturing process performed in the first sub-pixel P1 may be repeated as in FIGS. 4D to 4I. In an embodiment, in the third sub-pixel P3, the fifth hole H5 corresponding to the first hole H1 and the sixth hole H6 corresponding to the second hole H2 may be formed in the metal stacked structure 400 to provide an undercut structure or a tip shape. Thereafter, the third intermediate layer 320B and the third opposite electrode 330B may be stacked on the third sub-pixel P3, and the third intermediate layer 320B and the third opposite electrode 330B may be disconnected by the undercut structure. Therefore, the first portion of the third intermediate layer 320B-1 and the first portion of the third opposite electrode 330B-1 may be arranged in the fifth hole H5 and the sixth hole H6, and the second portion of the third intermediate layer 320B-2 and the second portion of the third opposite electrode 330B-2 may be disposed over the metal stacked structure 400. Next, the thin-film encapsulation layer 500 may be formed as in FIG. 5A, and accordingly, a portion of the thin-film encapsulation layer 500 may fill the fifth hole H5 and the sixth hole H6, and the remaining portion of the thin-film encapsulation layer 500 may be disposed over the second portion of the third opposite electrode 330B-2.

As shown in FIG. 5F, as in the process performed in FIG. 4D, the second portion of the third intermediate layer 320B-2, the second portion of the third opposite electrode 330B-2, and a portion of the thin-film encapsulation layer 500 may be removed. Portions of the second portion of the third intermediate layer 320B-2, the second portion of the third opposite electrode 330B-2, and the thin-film encapsulation layer 500, which are arranged in remaining areas excluding the pixel area of the third sub-pixel P3, may be removed at once by using dry etching. Accordingly, the second portion of the third intermediate layer 320B-2, the second portion of the third opposite electrode 330B-2, and the thin-film encapsulation layer 500 may be arranged only in the pixel area of the third sub-pixel P3.

In such an embodiment, after going through the manufacturing process described above with reference to FIGS. 5A to 5F, the intermediate layer 320 and the opposite electrode 330 in each of the pixel area of the first sub-pixel P1, the second sub-pixel P2, and the third sub-pixel P3 may be separated by the undercut structure of the metal stacked structure 400, and the thin-film encapsulation layer 500 may be arranged only in the pixel area of the first sub-pixel P1, the second sub-pixel P2, and the third sub-pixel P3 to form a structure in which each sub-pixel unit is sealed.

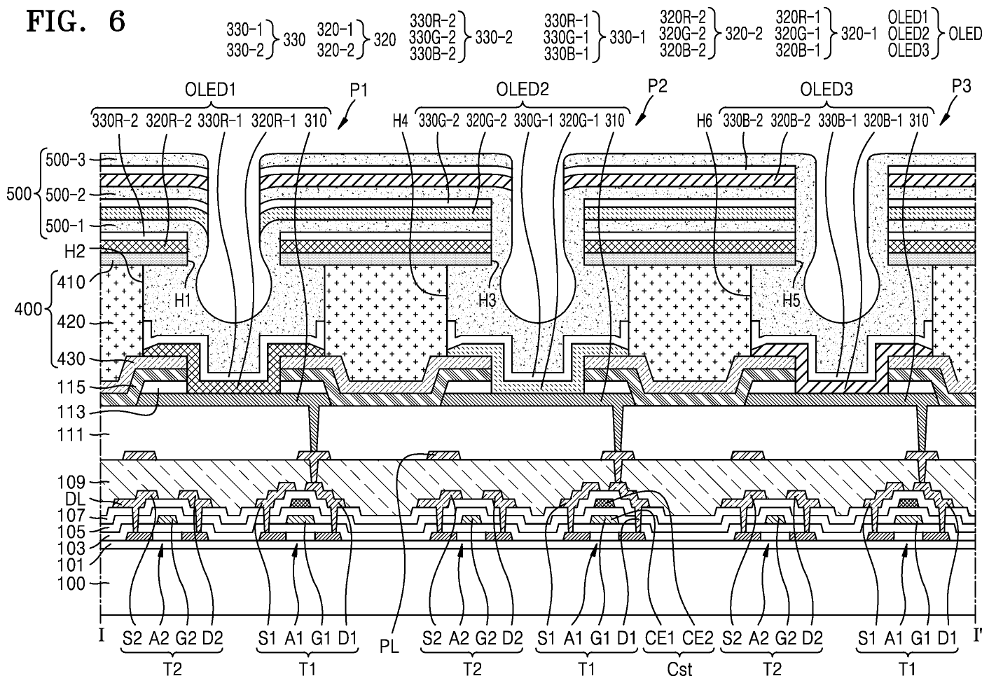

FIG. 6 is a cross-sectional view schematically illustrating a portion of a display device according to an alternative embodiment.

Referring to FIG. 6, an alternative embodiment of display device may be substantially the same as the embodiment described above with reference to FIG. 3 except for the intermediate layer 320, the opposite electrode 330, and the thin-film encapsulation layer 500. The same or like elements shown in FIG. 6 are labeled with the same reference characters as used above to describe the embodiment of the display device shown in FIG. 3, and any repetitive detailed description thereof will hereinafter be omitted or simplified.

Referring to FIG. 6, an intermediate layer 320 may be disposed on the sub-pixel electrode 310, and the opposite electrode 330 may be disposed on the intermediate layer 320. The intermediate layer 320 and the opposite electrode 330 may be separated individually in the plurality of organic light-emitting diodes OLED and may correspond to the plurality of sub-pixel electrodes 310.

The intermediate layer 320 and the opposite electrode 330 may each be separated by the undercut structure of the metal stacked structure 400. The intermediate layer 320 and the opposite electrode 330 may each be disconnected by the first hole H1 and the second hole H2 of the metal stacked structure 400. Therefore, the intermediate layer 320 may include the first portion of the intermediate layer 320-1 and the second portion of the intermediate layer 320-2, and the opposite electrode 330 may include the first portion of the opposite electrode 330-1 and the second portion of the opposite electrode 330-2. In such an embodiment, the first portion of the intermediate layer 320-1 and the first portion of the opposite electrode 330-1 may be disposed over the sub-pixel electrode 310 in areas of the first hole H1 and the second hole H2, and the second portion of the intermediate layer 320-2 and the second portion of the opposite electrode 330-2 may be disposed over the metal stacked structure 400.

The second portion of the intermediate layer 320-2 and the second portion of the opposite electrode 330-2 may extend to the non-pixel area. In an embodiment, the second portion of the intermediate layer 320-2 and the second portion of the opposite electrode 330-2 may also be disposed on the second sub-metal layer 420 of the metal stacked structure 400. That is, the second portion of the intermediate layer 320-2 and the second portion of the opposite electrode 330-2 may be arranged in an area excluding the emission area of first sub-pixel P1, the second sub-pixel P2, and the third sub-pixel P3. Accordingly, the intermediate layer 320 and the opposite electrode 330 of each of the first sub-pixel P1, the second sub-pixel P2, and the third sub-pixel P3 may be stacked in the non-pixel area. In such an embodiment, the second portion of the first intermediate layer 320R-2, the second portion of the first opposite electrode 330R-2, the second portion of the second intermediate layer 320G-2, the second portion of the second opposite electrode 330G-2, the second portion of the third intermediate layer 320B-2, and the second portion of the third opposite electrode 330B-2 may be sequentially stacked.

In addition, the thin-film encapsulation layer 500 may be disposed on the intermediate layer 320 and the opposite electrode 330 of each sub-pixel. The thin-film encapsulation layer 500 may include a first thin-film encapsulation layer 500-1 to seal the first sub-pixel P1, a second thin-film encapsulation layer 500-2 to seal the second sub-pixel P2, and a third thin-film encapsulation layer 500-3 to seal the third sub-pixel P3. The first thin-film encapsulation layer 500-1 may be disposed over the first opposite electrode 330R and may fill the first hole H1 and the second hole H2. The second thin-film encapsulation layer 500-2 may be disposed over the second opposite electrode 330G and may fill the third hole H3 and the fourth hole H4. The third thin-film encapsulation layer 500-3 may be disposed over the third opposite electrode 330B and may fill the fifth hole H5 and the sixth hole H6.

In such an embodiment, the thin-film encapsulation layer 500 may fill areas between the intermediate layer 320 and the opposite electrode 330 of each sub-pixel that are sequentially stacked in the non-pixel area. In such an embodiment, in the non-pixel area, the first thin-film encapsulation layer 500-1 may be arranged between the second portion of the first opposite electrode 330R-2 and the second portion of the second intermediate layer 320G-2. In the non-pixel area, the second thin-film encapsulation layer 500-2 may be arranged between the second portion of the second opposite electrode 330G-2 and the second portion of the third intermediate layer 320B-2. In the non-pixel area, the third thin-film encapsulation layer 500-3 may be disposed on the second portion of the third opposite electrode 330B-2. Accordingly, because the thin-film encapsulation layer 500 is formed to be collectively defined by the first thin-film encapsulation layer 500-1, the second thin-film encapsulation layer 500-2, and the third thin-film encapsulation layer 500-3, a structure in which each sub-pixel unit is sealed may be formed.

In such an embodiment, as described above, the display device may not go through a dry etching process for removing a portion of the intermediate layer 320, the opposite electrode 330, and the thin-film encapsulation layer 500. Accordingly, in such an embodiment, the display device may simplify the manufacturing process and implement the same effect as the display device according to an embodiment described above. In such an embodiment, the display device s may improve the resolution of the display device and implement an image of high quality. In addition, as the intermediate layer 320 and the opposite electrode 330 are disconnected by the metal stacked structure 400, lateral leakage current may not occur, and driving resistance may be reduced by electrically connecting the first portion of the opposite electrode 330-1 with the second sub-metal layer 420 of the metal stacked structure 400. In addition, even if defects such as a dark spot may occur, as the thin-film encapsulation layer 500 seals each of the sub-pixels, inhibiting growth of the dark spot may be implemented at the same time.

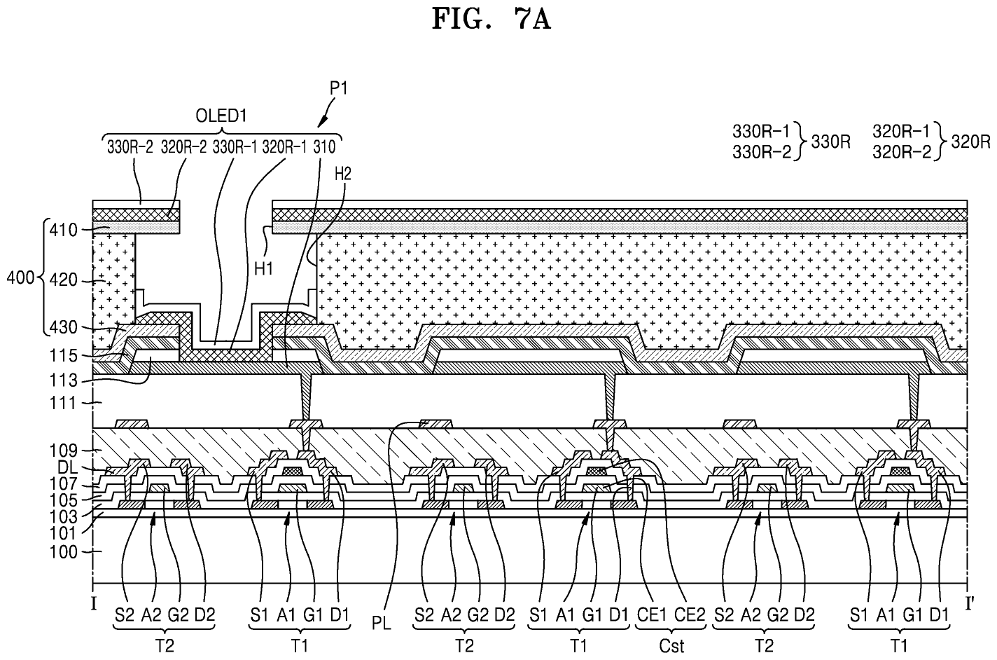

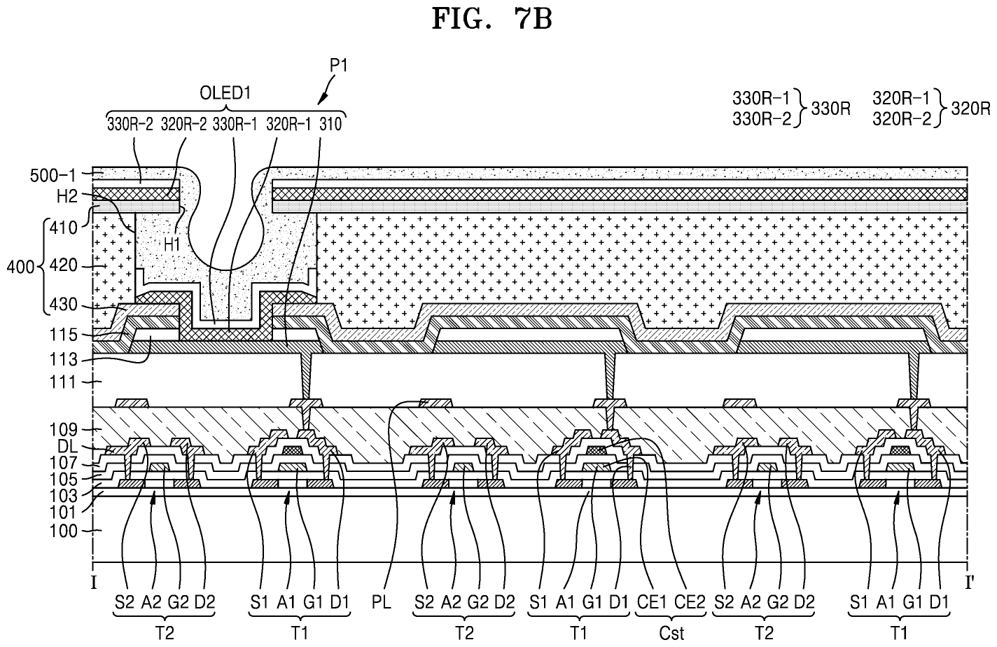

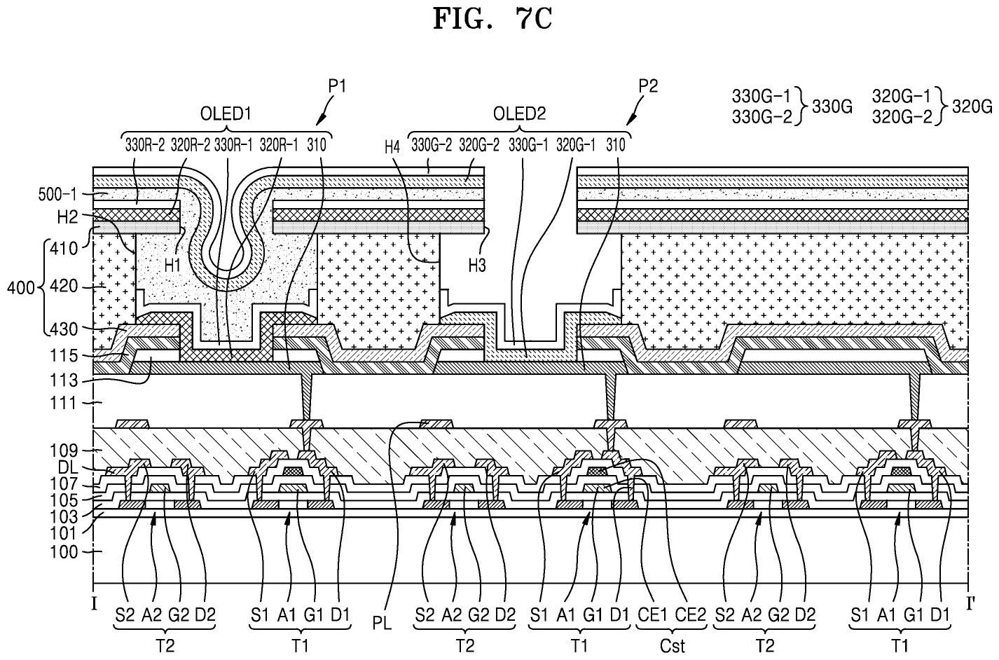

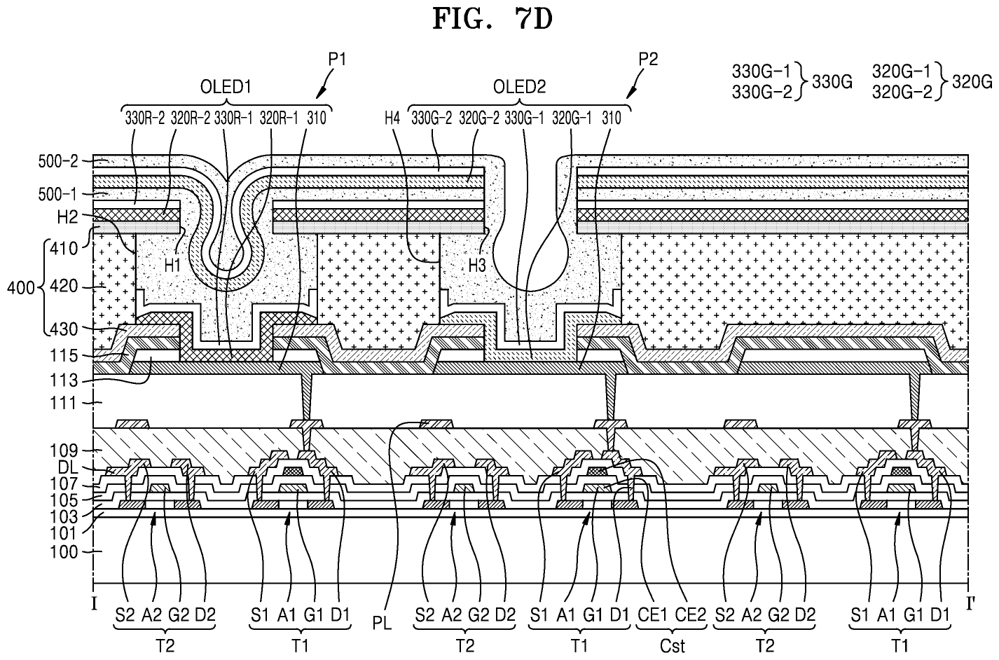

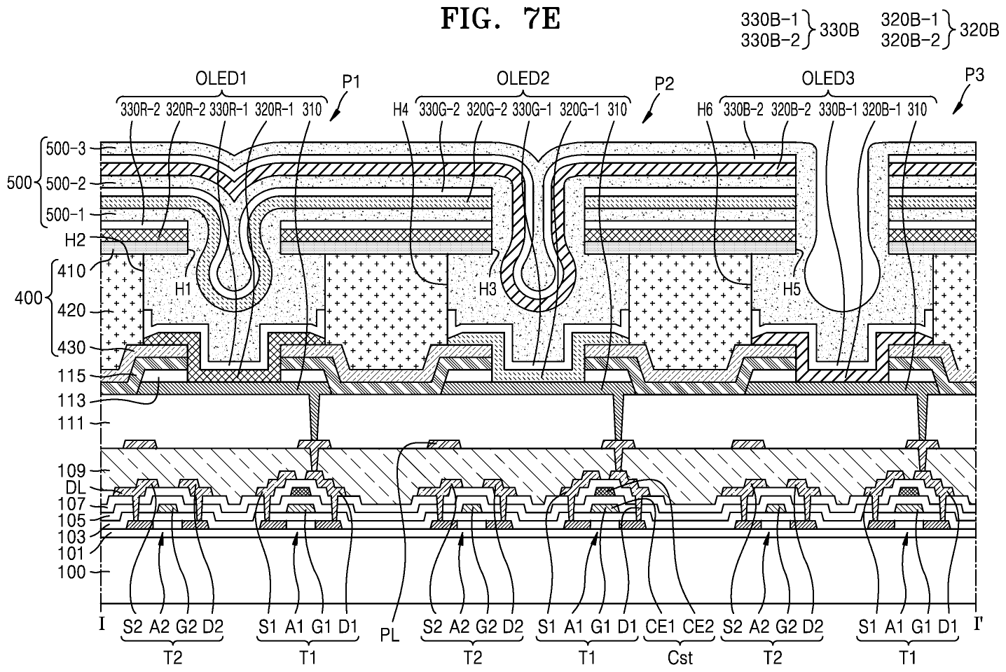

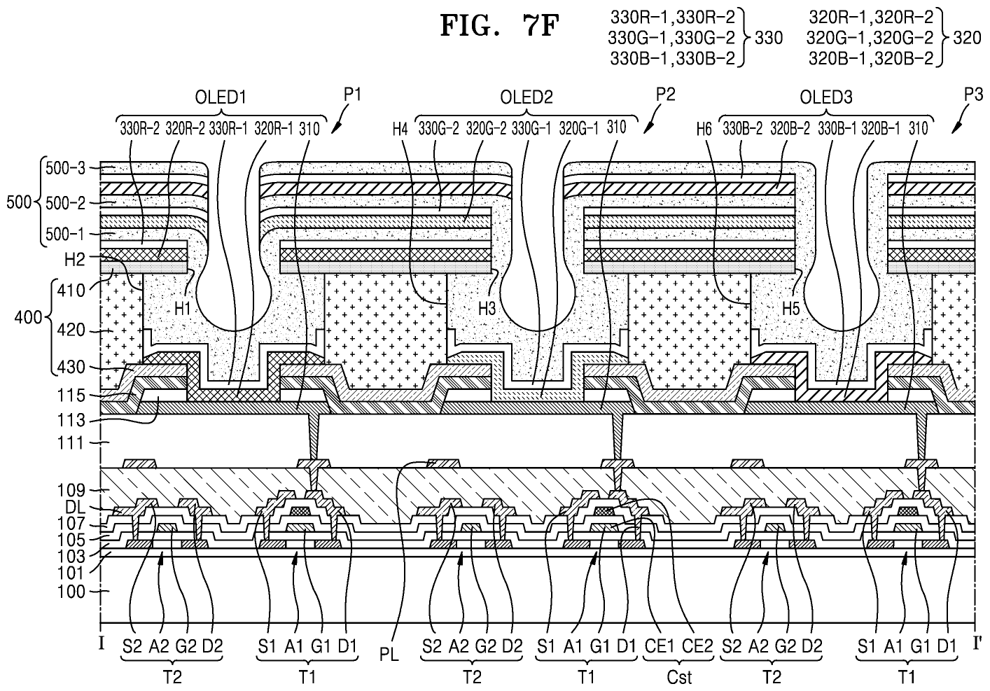

FIGS. 7A to 7F are cross-sectional views sequentially illustrating a process of manufacturing a display device according to an alternative embodiment.

Referring to FIGS. 7A to 7F, a process of manufacturing a display device may be the same as those described above with reference to FIGS. 3 to 5F except for the intermediate layer 320, the opposite electrode 330, and the thin-film encapsulation layer 500. The same or like elements shown in FIGS. 7A to 7F are labeled with the same reference characters as used above to describe the embodiment of a process of manufacturing a display device shown in FIGS. 3 to 5F, and any repetitive detailed description thereof will hereinafter be omitted or simplified.

In an embodiment, referring to FIG. 7A, the first sub-pixel P1 of the display device may go through the same manufacturing process as that described above with reference to FIGS. 4A to 4I. That is, the first hole H1 and the second hole H2 of the metal stacked structure 400 may be formed in the first sub-pixel P1, and the edge of the first sub-metal layer 410 defining the first hole H1 may protrude toward the center of the first hole H1 more than the edge of the second sub-metal layer 420 defining the second hole H2, thereby providing an undercut structure or a tip shape. Thereafter, the first intermediate layer 320R and the first opposite electrode 330R may be sequentially stacked, and the first intermediate layer 320R and the first opposite electrode 330R may be disconnected by the undercut structure of the metal stacked structure 400. Therefore, the first portion of the first intermediate layer 320R-1 and the first portion of the first opposite electrode 330R-1 may be arranged in the first hole H1 and the second hole H2, and the second portion of the first intermediate layer 320R-2 and the second portion of the first opposite electrode 330R-2 may be disposed over the metal stacked structure 400.

Next, as shown in FIG. 7B, the first thin-film encapsulation layer 500-1 sealing the first sub-pixel P1 may be formed on the disconnected second portion of the first opposite electrode 330R-2. The first thin-film encapsulation layer 500-1 may include at least one inorganic encapsulation layer only, but is not limited thereto, and alternatively, the first thin-film encapsulation layer 500-1 may include at least one organic encapsulation layer and at least one inorganic encapsulation layer. A portion of the first thin-film encapsulation layer 500-1 may fill the hole of the first protective layer 113, the hole of the first insulating layer 115, and the first hole H1 and the second hole H2 of the metal stacked structure 400. In the remaining areas excluding the first sub-pixel P1, the first thin-film encapsulation layer 500-1 may be disposed on the second portion of the first intermediate layer 320R-2 and the second portion of the first opposite electrode 330R-2.

Next, referring to FIG. 7C, the second sub-pixel P2 of the display device may go through the same manufacturing process as that described above with reference to FIGS. 4A to 4I. That is, the third hole H3 and the fourth hole H4 of the metal stacked structure 400 may be formed in the second sub-pixel P2, and the edge of the first sub-metal layer 410 defining the third hole H3 may protrude toward the center of the third hole H3 more than the edge of the second sub-metal layer 420 defining the fourth hole H4, thereby providing an undercut structure or a tip shape. Thereafter, the second intermediate layer 320G and the second opposite electrode 330G may be sequentially stacked, and the second intermediate layer 320G and the second opposite electrode 330G may be disconnected by the undercut structure of the metal stacked structure 400. Therefore, the first portion of the second intermediate layer 320G-1 and the first portion of the second opposite electrode 330G-1 may be arranged in the third hole H3 and the fourth hole H4, and the second portion of the second intermediate layer 320G-2 and the second portion of the second opposite electrode 330G-2 may be disposed over the first thin-film encapsulation layer 500-1.

Next, as shown in FIG. 7D, the second thin-film encapsulation layer 500-2 sealing the second sub-pixel P2 may be formed on the disconnected second portion of the second opposite electrode 330G-2. The second thin-film encapsulation layer 500-2 may include at least one inorganic encapsulation layer only, but is not limited thereto, and alternatively, the second thin-film encapsulation layer 500-2 may include at least one organic encapsulation layer and at least one inorganic encapsulation layer. A portion of the second thin-film encapsulation layer 500-2 may fill the hole of the first protective layer 113, the hole of the first insulating layer 115, and the third hole H3 and the fourth hole H4 of the metal stacked structure 400. In the remaining areas excluding the second sub-pixel P2, the second thin-film encapsulation layer 500-2 may be disposed on the second portion of the second intermediate layer 320G-2 and the second portion of the second opposite electrode 330G-2.

Next, referring to FIG. 7E, the third sub-pixel P3 of the display device may go through the same manufacturing process as that described above with reference to FIGS. 4A to 4I. That is, the fifth hole H5 and the sixth hole H6 of the metal stacked structure 400 may be formed in the third sub-pixel P3, and the edge of the first sub-metal layer 410 defining the fifth hole H5 may protrude toward the center of the fifth hole H5 more than the edge of the second sub-metal layer 420 defining the sixth hole H6, thereby providing an undercut structure or a tip shape. Thereafter, the third intermediate layer 320B and the third opposite electrode 330B may be sequentially stacked, and the third intermediate layer 320B and the third opposite electrode 330B may be disconnected by the undercut structure of the metal stacked structure 400. Therefore, the first portion of the third intermediate layer 320B-1 and the first portion of the third opposite electrode 330B-1 may be arranged in the fifth hole H5 and the sixth hole H6, and the second portion of the third intermediate layer 320B-2 and the second portion of the third opposite electrode 330B-2 may be disposed over the second thin-film encapsulation layer 500-2.

In addition, the third thin-film encapsulation layer 500-3 sealing the third sub-pixel P3 may be formed on the second portion of the third opposite electrode 330B-2. The third thin-film encapsulation layer 500-3 may include at least one inorganic encapsulation layer only, but is not limited thereto, and alternatively, the third thin-film encapsulation layer 500-3 may include at least one organic encapsulation layer and at least one inorganic encapsulation layer. A portion of the third thin-film encapsulation layer 500-3 may fill the hole of the first protective layer 113, the hole of the first insulating layer 115, and the fifth hole H5 and the sixth hole H6 of the metal stacked structure 400. In the remaining areas excluding the third sub-pixel P3, the third thin-film encapsulation layer 500-3 may be disposed on the second portion of the third intermediate layer 320B-2 and the second portion of the third opposite electrode 330B-2.

Next, as shown in FIG. 7F, a portion of the second portion of the second intermediate layer 320G-2, the second portion of the second opposite electrode 330G-2, the second thin-film encapsulation layer 500-2, the second portion of the third intermediate layer 320B-2, the second portion of the third opposite electrode 330B-2, and the third thin-film encapsulation layer 500-3 may be removed. In an embodiment, portions of the second portion of the second intermediate layer 320G-2, the second portion of the second opposite electrode 330G-2, the second thin-film encapsulation layer 500-2, the second portion of the third intermediate layer 320B-2, the second portion of the third opposite electrode 330B-2, and the third thin-film encapsulation layer 500-3, which are overlapping the emission area of the first sub-pixel P1 and the emission area of the second sub-pixel P2, may be removed at once by using dry etching. Accordingly, only the first thin-film encapsulation layer 500-1 may be disposed over the emission area of the first sub-pixel P1, the second thin-film encapsulation layer 500-2 may be disposed over the emission area of the second sub-pixel P2, and the third thin-film encapsulation layer 500-3 may be disposed over the emission area of the third sub-pixel P3. In addition, because the intermediate layer 320, the opposite electrode 330, and the thin-film encapsulation layer 500 are not etched in the non-pixel area, and the intermediate layer 320, the opposite electrode 330, and the metal stacked structure 400 of each sub-pixel may be stacked on the metal stacked structure 400. In such an embodiment, the first intermediate layer 320R, the first opposite electrode 330R, the first thin-film encapsulation layer 500-1, the second intermediate layer 320G, the second opposite electrode 330G, the second thin-film encapsulation layer 500-2, the third intermediate layer 320B, the third opposite electrode 330B, and the third thin-film encapsulation layer 500-3 may be sequentially stacked on the metal stacked structure 400.

In such an embodiment, after going through the manufacturing process such as those in FIGS. 7A to 7F, the intermediate layer 320 and the opposite electrode 330 in each of the pixel area of the first sub-pixel P1, the second sub-pixel P2, and the third sub-pixel P3 may be separated by the undercut structure of the metal stacked structure 400, and the thin-film encapsulation layer 500 may form a structure in which each sub-pixel unit is sealed.

The display device according to an embodiment, as described above, may reduce the generation of dark spots and improve resolution by forming a metal stacked structure instead of a bank layer and shortening an intermediate layer and a second electrode.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first sub-pixel, a second sub-pixel, and a third sub-pixel, which emit light of different colors from each other, respectively;
a substrate, on which a pixel area, in which the first sub-pixel, the second sub-pixel and the third sub-pixel are arranged, and a non-pixel area, in which a plurality of sub-pixels are not arranged, are defined;
a thin-film transistor disposed on the substrate;
a planarization layer covering the thin-film transistor;
a first electrode disposed on the planarization layer and connected to the thin-film transistor;
a first insulating layer covering an edge of the first electrode and extending to the non-pixel area;
a first protective layer disposed between the first electrode and the first insulating layer;
a metal stacked structure disposed on the first insulating layer in the non-pixel area, wherein the metal stacked structure includes a plurality of sub-metal layers;
a first portion of an intermediate layer disposed on the first electrode;
a first portion of a second electrode disposed on the first portion of the intermediate layer; and
a second portion of the intermediate layer and a second portion of the second electrode disposed on the metal stacked structure, wherein
the first portion of the intermediate layer and the first portion of the second electrode are disconnected from the second portion of the intermediate layer and the second portion of the second electrode by the metal stacked structure.

2. The display device of claim 1, wherein
the first portion of the second electrode is electrically connected to the metal stacked structure, and
the metal stacked structure is connected to a power voltage line.

3. The display device of claim 1, wherein
the metal stacked structure comprises a first sub-metal layer and a second sub-metal layer having different etching ratios from each other,
a first hole corresponding to an emission area of the plurality of sub-pixels is defined in the first sub-metal layer, and
a second hole is defined in the second sub-metal layer under the first sub-metal layer, wherein the second hole has a diameter greater than a diameter of the first hole and overlaps the first hole.

4. The display device of claim 3, wherein
an edge of the first sub-metal layer defining the first hole protrudes toward a center of the first hole from a point where a side surface of the second sub-metal layer defining the second hole meets a bottom surface of the first sub-metal layer, and
the first portion of the intermediate layer and the first portion of the second electrode are disposed in the second hole.

5. The display device of claim 4, wherein the first portion of the second electrode contacts the side surface of the second sub-metal layer defining the second hole.

6. The display device of claim 3, wherein
the metal stacked structure further comprises a third sub-metal layer disposed under the second sub-metal layer, and
the third sub-metal layer comprises a same material as the first sub-metal layer.

7. The display device of claim 3, wherein the metal stacked structure has a planar shape of a mesh pattern.

8. The display device of claim 1, wherein the first protective layer comprises a transparent conductive oxide.

9. The display device of claim 3, further comprising:
a thin-film encapsulation layer at least partially filling the first hole and the second hole.

10. The display device of claim 1, wherein
the intermediate layer comprises an organic emission layer which emits light, and
the organic emission layer of each of the first sub-pixel, the second sub-pixel, and the third sub-pixel emits light of different colors from each other.

11. The display device of claim 1, wherein the second portion of the intermediate layer and the second portion of the second electrode extend to the non-pixel area.

12. The display device of claim 11, wherein a second portion of an intermediate layer of the first sub-pixel, a second portion of an intermediate layer of the second sub-pixel, and a second portion of an intermediate layer of the third sub-pixel are sequentially stacked on the metal stacked structure.

13. The display device of claim 12, further comprising:
a thin-film encapsulation layer filling areas between the second portion of the intermediate layer of the first sub-pixel, the second portion of the intermediate layer of the second sub-pixel, and the second portion of the intermediate layer of the third sub-pixel.

14. A method of manufacturing a display device comprising a pixel area in which a first sub-pixel, a second sub-pixel, and a third sub-pixel which emit light of different colors from each other, respectively, are arranged, and a non-pixel area in which a plurality of sub-pixels are not arranged, the method comprising:
providing a thin-film transistor on a substrate;
providing a planarization layer on the substrate to cover the thin-film transistor;
providing a sub-pixel electrode on the planarization layer, wherein the sub-pixel electrode is connected to the thin-film transistor;
providing a first insulating layer covering an edge of the sub-pixel electrode and extending to the non-pixel area;
providing a metal stacked structure on the first insulating layer, wherein the metal stacked structure comprises a first sub-metal layer and a second sub-metal layer;
forming a first hole, corresponding to an emission area of the first sub-pixel, in the first sub-metal layer;
forming a second hole in the second sub-metal layer, which is disposed under the first sub-metal layer, wherein the second hole has a diameter greater than a diameter of the first hole and overlaps the first hole;
providing a first portion of a first intermediate layer on the sub-pixel electrode of the first sub-pixel;
providing a first portion of a first opposite electrode on the first portion of the first intermediate layer; and
providing a second portion of the first intermediate layer and a second portion of the first opposite electrode on the metal stacked structure, wherein
the first portion of the first intermediate layer and the first portion of the first electrode are disconnected from the second portion of the first intermediate layer and the second portion of the first electrode by the metal stacked structure.

15. The method of claim 14, wherein the forming the first hole comprises:
forming a photoresistor on the metal stacked structure and performing a photolithography process; and
performing dry etching on the first sub-metal layer and the second sub-metal layer.

16. The method of claim 15, wherein the forming the second hole comprises:
etching the second sub-metal layer in a way such that an edge of the first sub-metal layer defining the first hole protrudes more toward a center of the first hole from a point where a side surface of the second sub-metal layer defining the second hole meets a bottom surface of the first sub-metal layer.

17. The method of claim 14, further comprising:
forming a hole overlapping the first hole in the first insulating layer by performing dry etching.

18. The method of claim 17, further comprising:
providing a first protective layer between the first insulating layer and the sub-pixel electrode; and
forming a hole overlapping the first hole in the first protective layer by performing wet etching.

19. The method of claim 14, further comprising:
providing a first thin-film encapsulation layer to at least partially fill the first hole and the second hole.

20. The method of claim 19, further comprising:
performing dry etching on portions of the second portion of the first intermediate layer, the second portion of the first opposite electrode, and the first thin-film encapsulation layer, which are arranged in remaining areas excluding the pixel area of the first sub-pixel.

21. The method of claim 20, further comprising:
forming a third hole, corresponding to an emission area of the second sub-pixel, in the first sub-metal layer;
forming a fourth hole in the second sub-metal layer, wherein the fourth hole has a diameter greater than a diameter of the third hole and overlaps the third hole;
providing a first portion of a second intermediate layer on the sub-pixel electrode of the second sub-pixel;
providing a first portion of a second opposite electrode on the first portion of the second intermediate layer;
providing a second portion of the second intermediate layer and a second portion of the second opposite electrode on the metal stacked structure;
providing a second thin-film encapsulation layer to fill at least a portion of the third hole and the fourth hole; and
performing dry etching on portions of the second portion of the second intermediate layer, the second portion of the second opposite electrode, and the second thin-film encapsulation layer, which are arranged in remaining areas excluding the pixel area of the second sub-pixel.

22. The method of claim 21, further comprising:
forming a fifth hole, corresponding to an emission area of the third sub-pixel, in the first sub-metal layer;
forming a sixth hole in the second sub-metal layer, wherein the sixth hole has a diameter greater than a diameter of the fifth hole and overlapping the fifth hole;
providing a first portion of a third intermediate layer on the sub-pixel electrode of the third sub-pixel;
providing a first portion of a third opposite electrode on the first portion of the third intermediate layer;
providing a second portion of the third intermediate layer and a second portion of the third opposite electrode on the metal stacked structure;
providing a third thin-film encapsulation layer to fill at least a portion of the fifth hole and the sixth hole; and
performing dry etching on portions of the second portion of the third intermediate layer, the second portion of the third opposite electrode, and the third thin-film encapsulation layer, which are arranged in remaining areas excluding the pixel area of the third sub-pixel.

23. The method of claim 19, further comprising:
forming a third hole, corresponding to an emission area of the second sub-pixel, in the first sub-metal layer, the second portion of the first intermediate layer, and the first thin-film encapsulation layer;
forming a fourth hole in the second sub-metal layer, wherein the fourth hole has a diameter greater than a diameter of the third hole and overlaps the third hole;
providing a first portion of a second intermediate layer on the sub-pixel electrode of the second sub-pixel;
providing a first portion of a second opposite electrode on the first portion of the second intermediate layer;
providing a second portion of the second intermediate layer and a second portion of the second opposite electrode on the metal stacked structure; and
providing a second thin-film encapsulation layer to at least partially fill the third hole and the fourth hole.

24. The method of claim 23, further comprising:
forming a fifth hole, corresponding to an emission area of the third sub-pixel, in the first sub-metal layer, the second portion of the first intermediate layer, the second portion of the first opposite electrode, the first thin-film encapsulation layer, the second portion of the second intermediate layer, the second portion of the second opposite electrode, and the second thin-film encapsulation layer;
forming a sixth hole in the second sub-metal layer, wherein the sixth hole has a diameter greater than a diameter of the fifth hole and overlaps the fifth hole;
providing a first portion of a third intermediate layer on the sub-pixel electrode of the third sub-pixel;
providing a first portion of a third opposite electrode on the first portion of the third intermediate layer;
providing a second portion of the third intermediate layer and a second portion of the third opposite electrode on the metal stacked structure; and
providing a third thin-film encapsulation layer to at least partially fill the fifth hole and the sixth hole.

25. The method of claim 24, further comprising:
performing dry etching on materials on the emission area of the first sub-pixel excluding the first thin-film encapsulation layer; and
performing dry etching on materials on the emission area of the second sub-pixel excluding the second thin-film encapsulation layer.
